(19) United States
(12) Patent Application Publication
(10) Pub. No.: US 2025/0055471 A1
(43) Pub. Date: Feb. 13, 2025

(54) SEMICONDUCTOR DEVICE

(71) Applicant: Renesas Electronics Corporation, Tokyo (JP)

(72) Inventors: Tomohiko EBATA, Tokyo (JP); Tetsuo MATSUI, Tokyo (JP)

(73) Assignee: Renesas Electronics Corporation, Tokyo (JP)

(21) Appl. No.: 18/798,978

(22) Filed: Aug. 9, 2024

(30) Foreign Application Priority Data
Aug. 9, 2023 (JP) 2023-129829

(51) Int. Cl. H03M 1/46; H03M 1/12

(52) U.S. Cl. CPC H03M 1/466; H03M 1/1245; H03M 1/462

(57) ABSTRACT

A semiconductor device is provided. The semiconductor device is capable of operating accurately by suppressing errors caused by dielectric relaxation phenomena. The semiconductor device includes a first capacitive element, a first switch circuit, a first inversion signal generating circuit, a second capacitive element, and a negative feedback circuit.

### CROSS-REFERENCE TO RELATED APPLICATION

The subject application claims priority under 35 U.S.C. § 119 to Japanese Patent Application No. 2023-129829 filed on Aug. 9, 2023. The entire disclosure of Japanese Patent Application No. 2023-129829 is incorporated herein by reference.

### BACKGROUND

This disclosure relates to a semiconductor device, for example, a semiconductor device capable of operating accurately by suppressing errors caused by dielectric relaxation phenomena.

There are disclosed techniques listed below.

### [Patent Document 1] Japanese Unexamined Patent Application Publication No. 2020-107985

In Patent Document 1, a charge redistribution type sequential comparison type AD conversion circuit that suppresses errors in AD conversion caused by dielectric relaxation phenomena is disclosed.

### SUMMARY

Not limited to the AD conversion circuit disclosed in Patent Document 1, in semiconductor devices to which a negative feedback circuit is applied, it is required to suppress errors caused by dielectric relaxation phenomena and operate accurately.

Other objects and novel features will become apparent from the description of this specification and the accompanying drawings.

A semiconductor device according to one embodiment of this disclosure includes a first capacitive element, a first switch circuit that applies a first input voltage to one end of the first capacitive element in a sampling mode and holds the first input voltage in the first capacitive element in a hold mode after the sampling mode, a first inversion signal generation circuit that generates a voltage that inverts the first input voltage in the sampling mode and holds the generated voltage in the bold mode, a second capacitive element to which the voltage generated by the first inversion signal generation circuit is applied to one end, and a negative feedback circuit that generates an output signal according to the voltage of a first node that is commonly connected to the other end of the first capacitive element and the other end of the second capacitive element in the hold mode and applies a first feedback signal corresponding to the output signal to one end of the first capacitive element.

This disclosure can provide a semiconductor device capable of operating accurately by suppressing errors caused by dielectric relaxation phenomena.

### BRIEF DESCRIPTION OF THE DRAWINGS

FIG. 1 is a circuit diagram showing a configuration example of a semiconductor device according to the first embodiment.

FIG. 2 is a timing chart showing the operation of the semiconductor device shown in FIG. 1.

FIG. 3 is a diagram showing an equivalent circuit of capacitive elements Cs, Cdac each having a dielectric relaxation phenomenon.

FIG. 4 is a timing chart showing the operation of the equivalent circuit shown in FIG. 3.

FIG. 5 is a circuit diagram showing a first modified example of the semiconductor device according to the first embodiment.

FIG. 6 is a timing chart showing the operation of the semiconductor device shown in FIG. 5.

FIG. 7 is a timing chart showing another example of the operation of the semiconductor device shown in FIG. 5.

FIG. 8 is a circuit diagram showing a configuration example of a semiconductor device according to the second embodiment.

FIG. 9 is a timing chart showing the operation of the semiconductor device shown in FIG. 8.

FIG. 10 is a circuit diagram showing a specific example of the semiconductor device shown in FIG. 8.

FIG. 11 is a circuit diagram showing a first modified example of the semiconductor device according to the second embodiment.

FIG. 12 is a circuit diagram showing a second modified example of the semiconductor device according to the second embodiment.

FIG. 13 is a timing chart showing the operation of the semiconductor device shown in FIG. 12.

FIG. 14 is a circuit diagram showing a specific example of the semiconductor device shown in FIG. 12.

FIG. 15 is a circuit diagram showing a configuration example of a semiconductor device according to the third embodiment.

FIG. 16 is a timing chart showing the operation of the semiconductor device shown in FIG. 15.

FIG. 17 is a circuit diagram showing a specific example of the semiconductor device shown in FIG. 15.

FIG. 18 is a circuit diagram showing a first modified example of the semiconductor device according to the third embodiment.

FIG. 19 is a timing chart showing the operation of the semiconductor device shown in FIG. 18.

FIG. 20 is a circuit diagram showing a second modified example of the semiconductor device according to the third embodiment.

FIG. 21 is a circuit diagram showing a configuration example of a semiconductor device according to the fourth embodiment.

FIG. 22 is a timing chart showing the operation of the semiconductor device shown in FIG. 21.

FIG. 23 is a circuit diagram showing a first configuration example of a semiconductor device that has been previously considered.

FIG. 24 is a timing chart showing the operation of the semiconductor device shown in FIG. 23.

FIG. 25 is a diagram showing an equivalent circuit of a capacitive element Cs having a dielectric relaxation phenomenon.

FIG. 26 is a circuit diagram showing a second configuration example of a semiconductor device that has been previously considered.

FIG. 27 is a timing chart showing the operation of the semiconductor device shown in FIG. 26.

### DETAILED DESCRIPTION

Hereinafter, embodiments will be described with reference to the drawings. Note that the drawings are simplified, so the technical scope of the embodiments should not be narrowly interpreted based on the descriptions in the drawings. Also, the same elements are denoted by the same symbols, and redundant descriptions are omitted.

In the following embodiments, for convenience, when necessary, the description is divided into multiple sections or embodiments. However, unless specifically stated, they are not unrelated to each other, and one may be a part or all of a modified example, application example, detailed description, supplementary explanation, etc. of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

### Preliminary Study by Inventors, etc.

Before describing the semiconductor device according to the present embodiment, a semiconductor device that the inventors, etc. have preliminarily studied will be described.

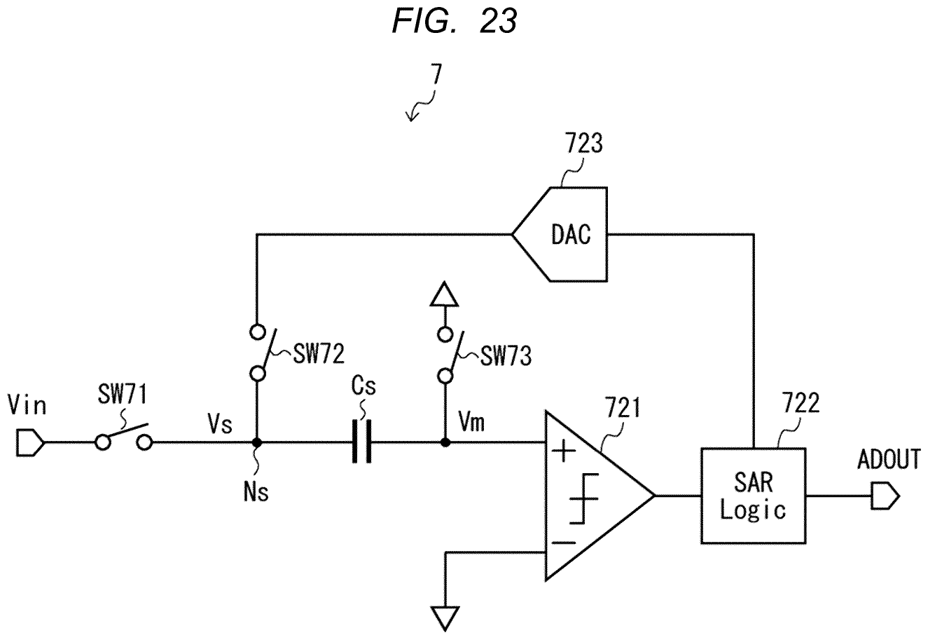

FIG. 23 is a circuit diagram showing a configuration example of the preliminarily studied semiconductor device 7. The semiconductor device 7 is a so-called single-input charge redistribution type successive approximation AD converter, which converts an analog input voltage Vin into a digital output signal ADOUT using a binary search algorithm.

Specifically, the semiconductor device 7 includes a comparator 721, a successive approximation register circuit (SAR Logic) 722, a DA converter 723, a capacitive element Cs, and switches SW71 to SW73.

The capacitive element Cs is provided between the non-inverting input terminal of the comparator 721 and a node Ns. The switch SW71 is provided between an input terminal (hereinafter referred to as input terminal Vin) where the input voltage Vin is supplied from outside the semiconductor device 7, and the node Ns (one end of the capacitive element Cs). The switch SW73 is provided between the non-inverting input terminal (the other end of the capacitive element Cs) of the comparator 721 and a reference voltage terminal where the reference voltage Vss is supplied. The reference voltage Vss is supplied to the inverting input terminal of the comparator 721.

The successive approximation register circuit 722 outputs a digital signal (a control signal for controlling the switches of the DA converter 723) according to the comparison result of the comparator 721, and also outputs an output signal ADOUT of the determined digital value. The DA converter 723 converts the digital signal output from the successive approximation register circuit 722 into an analog voltage and outputs it. Specifically, the DA converter 723 has multiple switches that switch on and off based on the digital signal of the successive approximation register circuit 722, and multiple capacitive elements with binary-weighted capacitance values, and performs DA conversion processing while redistributing the charges accumulated in each of the multiple capacitive elements based on the input voltage Vin and the reference voltage Vref by switching the connection of the multiple capacitive elements with the multiple switches. The switch SW72 is provided between the output of the DA converter 723 and the node Ns.

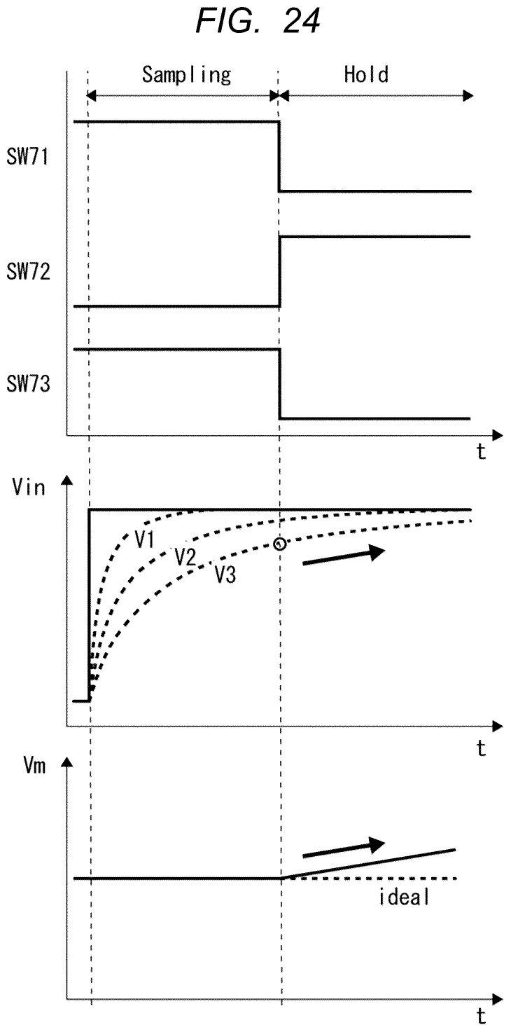

FIG. 24 is a timing chart showing the operation of the semiconductor device 7. Furthermore, each switch is designed to turn off by a low-level control signal and turn on by a high-level control signal. Furthermore, the operation modes of the semiconductor device 7 include at least a sampling mode and a hold mode.

First, in the sampling mode, the switch SW71 indicates an on state, the switch SW72 indicates an off state, and the switch SW73 indicates an on state. As a result, the input voltage Vin is sampled. That is, a charge corresponding to the input voltage Vin is accumulated at the node Ns (one end of the capacitor Cs). As a result, the voltage Vs of the node Ns ideally indicates the input voltage Vin. Subsequently, in the hold mode, the switch SW71 switches from on to off, the switch SW72 switches from off to on, and the switch SW73 switches from on to off. As a result, the sampled input voltage Vin is held in the capacitor Cs.

At this time, the semiconductor device 7 performs a sequential comparison operation of the output voltage of the DA converter 723, the input voltage Vin, using the comparator 721 and the sequential comparison register circuit 722, while redistributing the charges accumulated in each of the plurality of capacitors based on the input voltage Vin and the reference voltage Vref in the DA converter 723, using a plurality of switches to switch the connections of the plurality of capacitors.

However, the semiconductor device 7 had a problem that it could not operate accurately due to an error in AD conversion caused by dielectric relaxation.

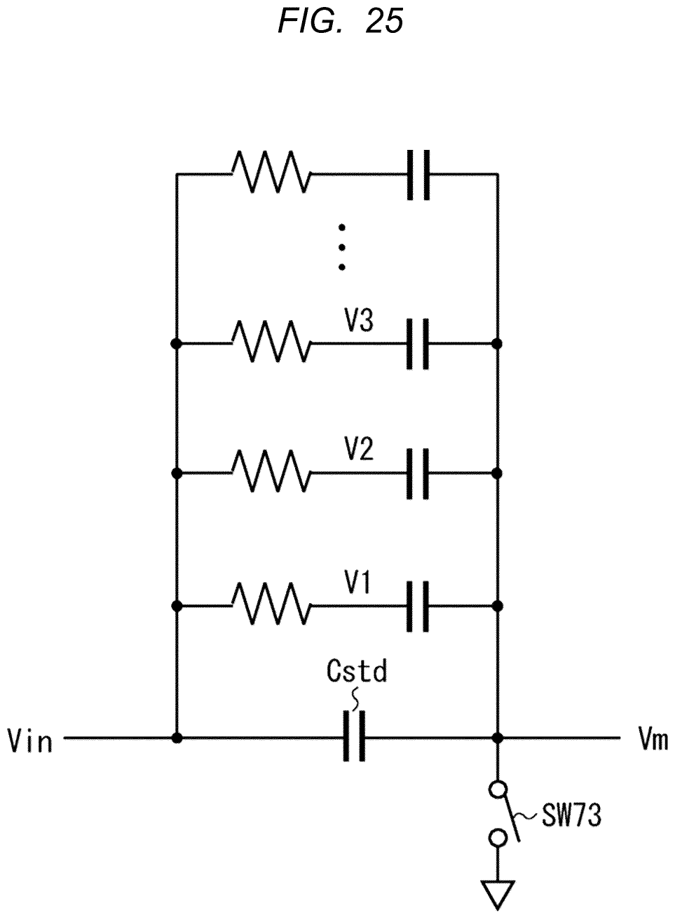

FIG. 25 is a diagram showing an equivalent circuit of a capacitor Cs having a dielectric relaxation phenomenon. As shown in FIG. 25, a plurality of series circuits composed of parasitic resistance and parasitic capacitance are connected in parallel to the capacitor Cs in addition to the true capacitance Cstd. It is known that the time constants of each of these multiple series circuits are different from each other and are a distributed constant model with a wide frequency band.

Therefore, in the semiconductor device 7, for example, as shown in FIG. 24, there is a possibility that the operation mode may switch from the sampling mode to the hold mode in a state where the input voltage Vin has not reached the ideal level (solid line) (dotted line). As a result, the voltage Vm of the non-inverting input terminal (the other end of the capacitor Cs) of the comparator 721 may fluctuate in the hold mode, and as a result, the semiconductor device 7 may not be able to perform AD conversion processing accurately.

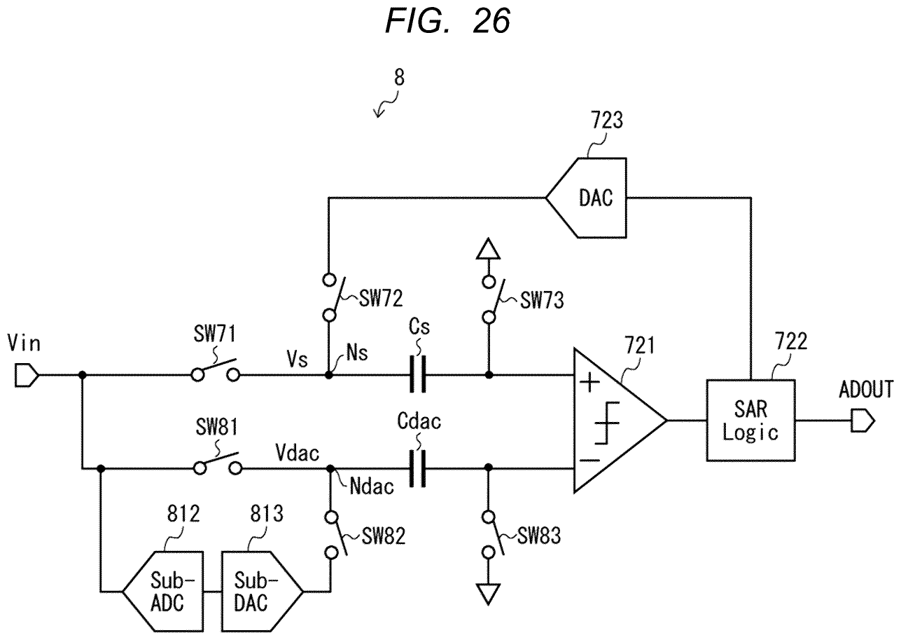

Therefore, the inventors considered the semiconductor device 8 next. FIG. 26 is a circuit diagram showing a configuration example of the semiconductor device 8 that was preliminarily examined. The semiconductor device 8 further includes a sub AD converter 812, a sub DA converter 813, a capacitor Cdac, and switches SW81 to SW83, compared to the semiconductor device 7.

The capacitor Cdac shows the same capacitance value as the capacitor Cs and is provided between the inverting input terminal of the comparator 721 and the node Ndac. The switch SW81 is provided between the input terminal Vin and the node Ndac (one end of the capacitor Cdac). The switch SW83 is provided between the inverting input terminal (the other end of the capacitor Cdac) of the comparator 721 and the reference voltage terminal. The sub AD converter 812 and the sub DA converter 813 are provided in parallel with the switch SW81 between the input terminal Vin and the node Ndac. The AD converter 812 converts the analog input voltage Vin into a digital signal and outputs it. The DA converter 813 converts the digital signal output from the AD converter 812 into an analog voltage and outputs it. The switch SW82 is provided between the output of the DA converter 813 and the node Ndac.

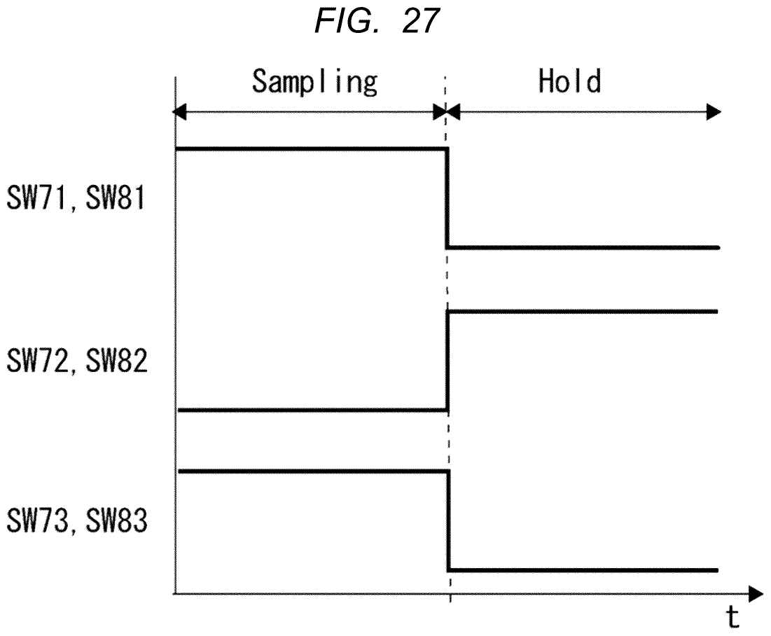

FIG. 27 is a timing chart showing the operation of the semiconductor device 8. Each switch is assumed to turn off by a low-level control signal and turn on by a high-level control signal. Furthermore, the operation modes of the semiconductor device 8 include at least a sampling mode and a hold mode.

Firstly, in the sampling mode, switches SW71 and SW81 indicate an on state, switches SW72 and SW82 indicate an off state, and switches SW73 and SW83 indicate an on state. As a result, the input voltage Vin is sampled. That is, at node Ns (one end of the capacitive element Cs), a charge corresponding to the input voltage Vin is accumulated. Also, at node Ndac (one end of the capacitive element Cdac), a charge corresponding to the input voltage Vin is accumulated. As a result, the voltage Vs at node Ns ideally indicates the input voltage Vin. Also, the voltage Vdac at node Ndac ideally indicates the input voltage Vin. Subsequently, in the hold mode, switches SW71 and SW81 switch from on to off, switches SW72 and SW82 switch from off to on, and switches SW73 and SW83 switch from on to off. As a result, the sampled input voltage Vin is held in the capacitive element Cs. Also, the sampled input voltage Vin is held in the capacitive element Cdac. Strictly speaking, it is desirable to have a sequence in which switch SW81 switches from on to off, switch SW82 switches from off to on, then switches SW73 and SW83 switch from on to off, switch SW71 switches from on to off, and switch SW72 switches from off to on. This is because it can eliminate the effects of errors in AD converter 812 and DA converter 813. However, this strict timing operation is not necessary when considering the effects of dielectric relaxation.

At this time, the semiconductor device 8 performs a sequential comparison operation of the output voltage of DA converter 723, the input voltage Vin, using comparator 721 and sequential comparison register circuit 722, while redistributing the charges accumulated in each of the plurality of capacitive elements based on the input voltage Vin and the reference voltage Vref, by switching the connections of the plurality of capacitive elements using a plurality of switches in DA converter 723.

Here, in the semiconductor device 8, an error in the input voltage Vin due to the dielectric relaxation phenomenon occurs in each of the capacitive elements Cs and Cdac. Therefore, in the semiconductor device 8, the comparator 721 can compare by canceling these error components. That is, the semiconductor device 8 can operate accurately by suppressing the error in AD conversion caused by the dielectric relaxation phenomenon.

The semiconductor device 8 shown in FIG. 26 was able to apply a dielectric relaxation countermeasure circuit to the inverting input terminal of comparator 721 because it is based on a single-ended input charge redistribution type sequential comparison type AD converter. On the other hand, there was a problem that a dielectric relaxation countermeasure circuit could not be applied to a place corresponding to the inverting input terminal of comparator 721 in a differential input charge redistribution type sequential comparison type AD converter or other existing circuits where negative feedback is applied. Therefore, a semiconductor device 1 that can meet such requirements was found.

### First Embodiment

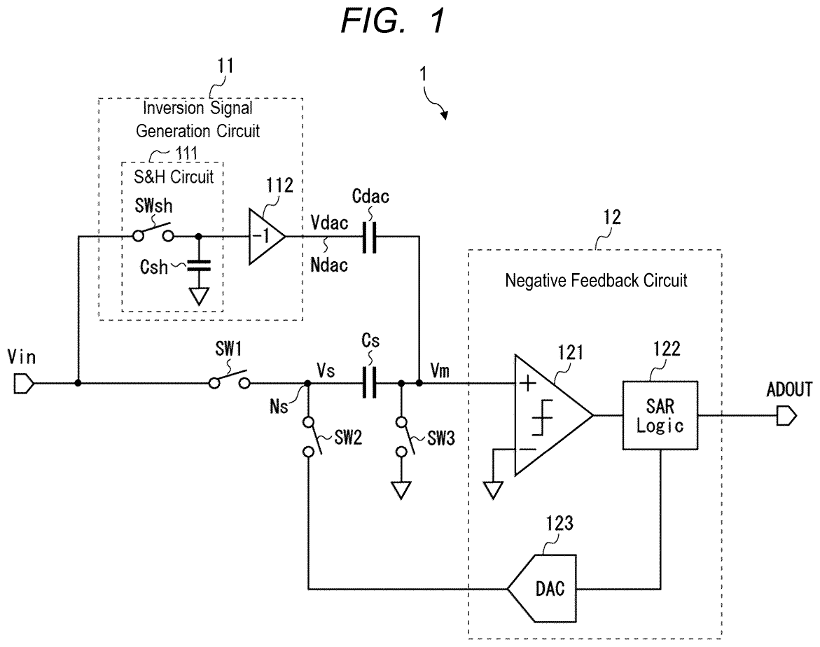

FIG. 1 is a circuit diagram showing a configuration example of a semiconductor device 1 according to the first embodiment. The semiconductor device 1 is a so-called charge redistribution type sequential comparison type AD converter, which converts an analog input voltage Vin into a digital output signal ADOUT using a binary search algorithm and outputs it.

Specifically, the semiconductor device 1 includes an inversion signal generation circuit 11, a negative feedback circuit 12, capacitive elements Cs and Cdac, and switches SW1 to SW3. The inversion signal generation circuit 11 includes a sample & hold circuit (S&H circuit) 111 and an inversion circuit 112. The negative feedback circuit 12 includes a comparator 121, a sequential comparison register circuit 122, and a DA converter 123. For example, switch SW1 constitutes a first switch circuit.

The capacitive element Cs is provided between the non-inverting input terminal of the comparator 121 and the node Ns. The switch SW1 is provided between an input terminal (hereinafter referred to as input terminal Vin) where an input voltage Vin is supplied from outside the semiconductor device 1, and a node Ns (one end of a capacitive element Cs). The switch SW3 is provided between a non-inverting input terminal of the comparator 121 (the other end of the capacitive element Cs) and a reference voltage terminal (hereinafter referred to as reference voltage terminal Vss) where a reference voltage Vss is supplied. The inverting input terminal of the comparator 121 is supplied with the reference voltage Vss.

The successive comparison register circuit 122 outputs a digital signal according to the comparison result of the comparator 121, and also outputs an output signal ADOUT of the determined digital value. The DA converter 123 converts the digital signal output from the successive comparison register circuit 122 into an analog voltage and outputs it. The switch SW2 is provided between the output of the DA converter 123 and the node Ns.

The capacitive element Cdac has the same capacitance value as the capacitive element Cs, and is provided between the non-inverting input terminal of the comparator 121 and the node Ndac. The inversion signal generation circuit 11 is provided between the input terminal Vin and the node Ndac (one end of the capacitive element Cdac). The sample & hold circuit 111 has a switch SWsh and a capacitive element Csh, and samples and holds the input voltage Vin. The inversion circuit 112 inverts the output voltage of the sample & hold circuit 111 and outputs it. Here, in the inversion of the inversion circuit 112, if the input of the inversion circuit 112 is x, the output of the inversion circuit 112 is y, and the common potential to be inverted by the inversion circuit 112 is Vcm1, the relationship y=−(x−Vcm1)+Vcm1 holds. Hereinafter, the voltage inversion by each inversion circuit means the relationship of the above formula. In the present embodiment, the case where the gain of the inversion circuit 112 is −1 will be described as an example. However, if the capacitive element Cdac is configured to show a capacitance value that satisfies Cdac=Cs/k, where the capacitance value of the capacitive element Cdac is Cdac and the capacitance value of the capacitive element Cs is Cs, the gain of the inversion circuit 112 may be −k.

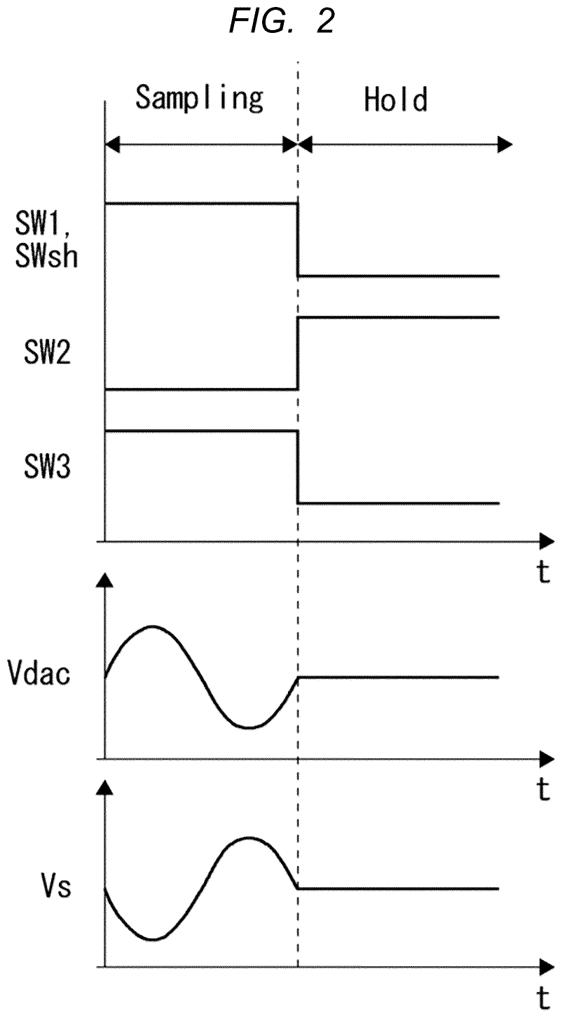

FIG. 2 is a timing chart showing the operation of the semiconductor device 1. Each switch is assumed to turn off by a low-level control signal and turn on by a high-level control signal. The operation modes of the semiconductor device 1 include at least a sampling mode and a hold mode.

First, in the sampling mode, the switches SW1 and SWsh show an on state, the switch SW2 shows an off state, and the switch SW3 shows an on state. As a result, the input voltage Vin is sampled. That is, a charge corresponding to the input voltage Vin is accumulated at the node Ns (one end of the capacitive element Cs). As a result, the voltage Vs of the node Ns ideally indicates the input voltage Vin. Also, a charge corresponding to the input voltage Vin is accumulated in the capacitive element Csh of the sample & hold circuit 111. As a result, the output voltage of the sample & hold circuit 111 ideally indicates the input voltage Vin. Also, the inversion circuit 112 inverts the output voltage of the sample & hold circuit 111 (ideally the input voltage Vin) and outputs it. As a result, the voltage Vdac of the node Ndac ideally indicates the voltage inverted from the input voltage Vin.

Then, in the hold mode, the switches SW1 and SWsh switch from on to off, the switch SW2 switches from off to on, and the switch SW3 switches from on to off. As a result, the sampled input voltage Vin is held in the capacitive element Cs, and the voltage inverted from the sampled input voltage Vin is held in the capacitive element Cdac. Strictly speaking, it is desirable to have a sequence in which the switch SWsh switches from on to off, the switch SW1 switches from on to off, and then the switch SW3 switches from on to off. This is because it can eliminate the influence of the error of the inversion signal generation circuit 11. However, this strict timing operation is not necessary when considering the influence of dielectric relaxation.

At this time, the negative feedback circuit 12 performs a sequential comparison operation using a comparator 121 and a sequential comparison register circuit 122, between the output voltage of the DA converter 123 and the input voltage Vin.

In the semiconductor device 1, an error occurs in the capacitive element Cs due to the dielectric relaxation phenomenon, and an error of opposite polarity occurs in the capacitive element Cdac due to the dielectric relaxation phenomenon. Therefore, at the voltage Vm of the non-inverting input terminal of the comparator 121, where the other ends of the capacitive elements Cs and Cdac are commonly connected, these error components are cancelled. As a result, the semiconductor device 1 can operate accurately.

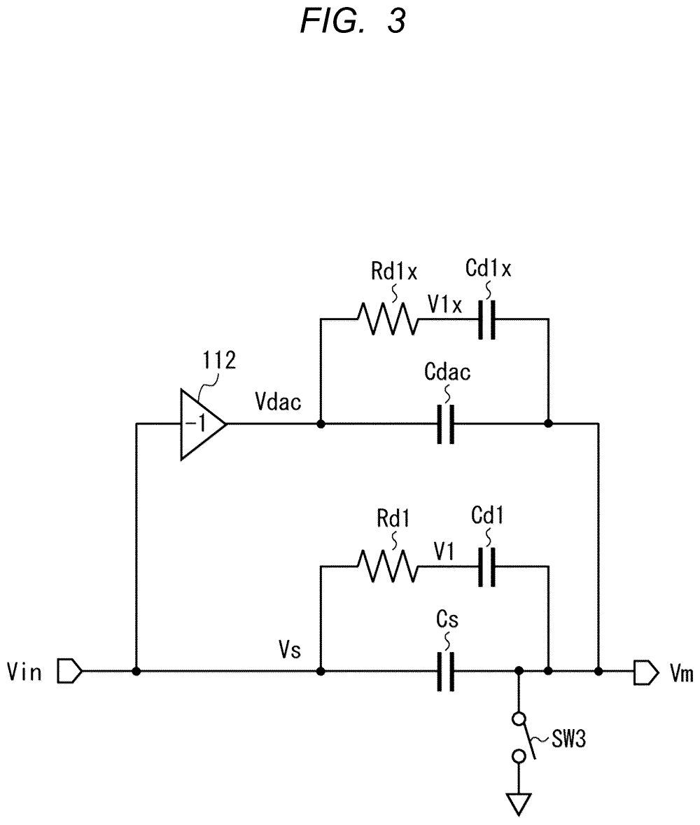

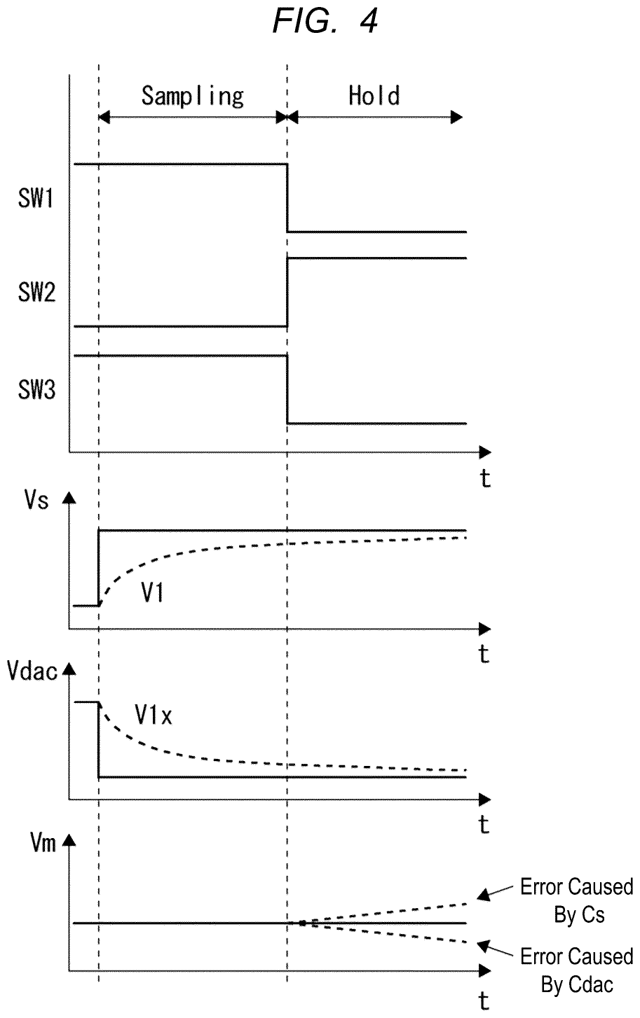

FIG. 3 is a diagram showing an equivalent circuit of capacitive elements Cs and Cdac, each having a dielectric relaxation phenomenon. FIG. 4 is a timing chart showing the operation of the equivalent circuit shown in FIG. 3.

As shown in FIG. 3, a capacitive element Cs considering the dielectric relaxation phenomenon has a series circuit consisting of a parasitic resistance Rd1 and a parasitic capacitance Cd1 provided in parallel. The time constant of this series circuit tends to be larger than the desired sampling time. Also, a capacitive element Cdac considering the dielectric relaxation phenomenon has a series circuit consisting of a parasitic resistance Rd1x and a parasitic capacitance Cd1x provided in parallel. The time constant of this series circuit tends to be larger than the desired sampling time. Here, for simplicity of explanation, a pair of RC time constants simulating dielectric relaxation is represented, but originally it is represented by a model with many time constants.

Therefore, in the semiconductor device 1, as shown in FIG. 4, there is a possibility that the operation mode switches from the sampling mode to the hold mode in a state where the input voltages Vs and Vdac have not reached the ideal level (solid line) (dotted line). However, the input voltage Vs includes an error of the input voltage Vin caused by the dielectric relaxation phenomenon, and the input voltage Vdac includes an error of the opposite polarity of the input voltage Vin caused by the dielectric relaxation phenomenon. Therefore, at the voltage Vm of the non-inverting input terminal of the comparator 121, where the other ends of the capacitive elements Cs and Cdac are commonly connected, these error components are cancelled. As a result, the semiconductor device 1 can operate accurately.

Thus, the semiconductor device 1 according to the present embodiment samples the input voltage Vin and the voltage inverted therefrom, and holds them in the capacitive elements Cs and Cdac, respectively, which are commonly connected to the non-inverting input terminal of the comparator 121. As a result, the semiconductor device 1 according to the present embodiment can cancel the error caused by the dielectric relaxation phenomenon and the error of the opposite polarity caused by the dielectric relaxation phenomenon, and can accurately capture the input voltage Vin and accurately convert it into a digital output signal ADOUT and output it.

### First Modified Example of Semiconductor Device 1

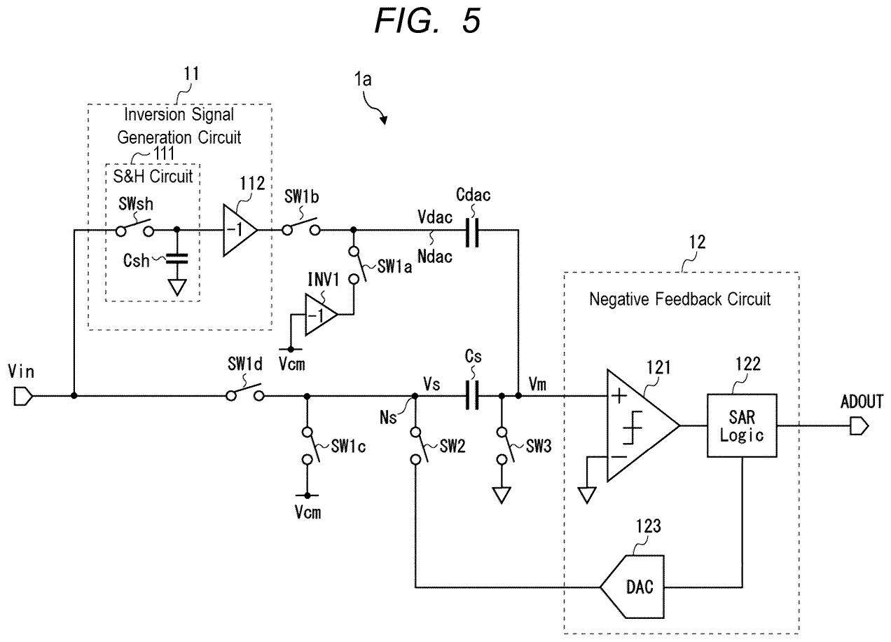

FIG. 5 is a circuit diagram showing a first modified example of the semiconductor device 1 as a semiconductor device la. The semiconductor device la is equipped with switches SW1a to SW1d instead of the switch SW1 compared to the semiconductor device 1. Switches SW1c and SW1d constitute a first switch circuit, and switches SW1a and SW1b constitute a second switch circuit.

Switch SW1a is provided between the node Ndac and the inverting circuit INV1 that generates the inverted voltage (−Vcm) of the common voltage Vcm. Switch SW1b is provided between the output of the inverting circuit 112 and the node Ndac. Switch SW1c is provided between the node Ns and the voltage supply terminal (hereinafter referred to as the voltage supply terminal Vcm) where the common voltage Vcm is supplied. Switch SW1d is provided between the input terminal Vin and the node Ns. In other words, switch SW1d is provided where switch SW1 was provided.

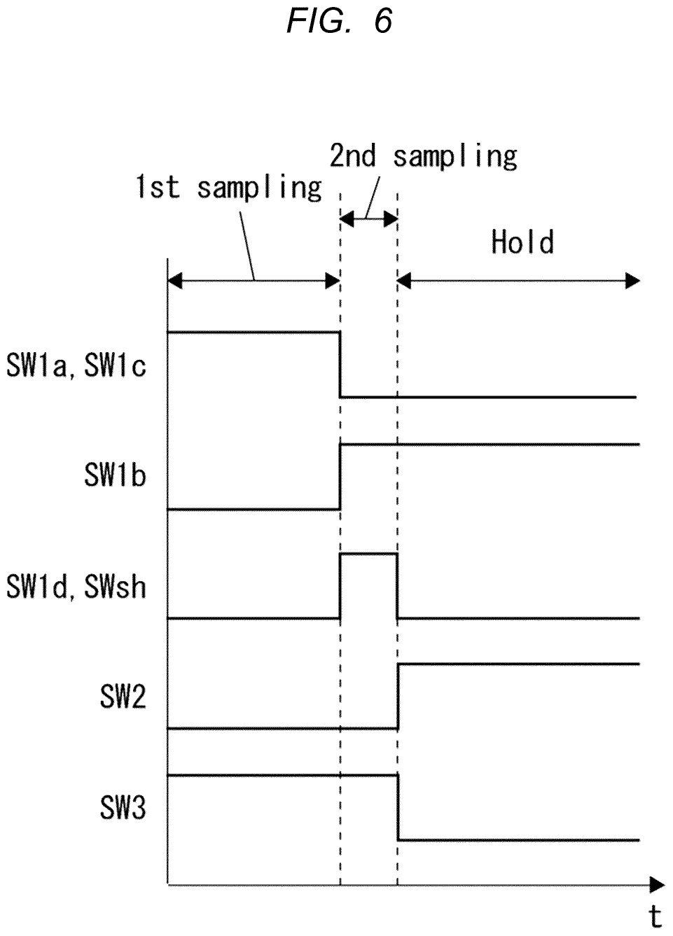

FIG. 6 is a timing chart showing the operation of the semiconductor device 1a. Each switch is configured to turn off by a low-level control signal and turn on by a high-level control signal. The operation modes of the semiconductor device 1a include at least a sampling mode and a hold mode. The sampling mode is composed of a first sampling mode and a second sampling mode.

First, in the first sampling mode, switches SW1a and SW1c indicate an on state, switch SW1b indicates an off state, switches SW1d and SWsh indicate an off state, switch SW2 indicates an off state, and switch SW3 indicates an on state. As a result, charges corresponding to the common voltage Vcm and the inverted voltage of the common voltage Vcm are accumulated at the nodes Ns (one end of the capacitor Cs) and Ndac (one end of the capacitor Cdac), respectively.

Subsequently, in the second sampling mode, switches SW1a and SW1c switch from on to off, switch SW1b switches from off to on, and switches SW1d and SWsh switch from off to on. As a result, the input voltage Vin is sampled. That is, a charge corresponding to the input voltage Vin is accumulated at the node Ns (one end of the capacitor Cs).

Also, in the second sampling mode, a charge corresponding to the input voltage Vin is accumulated in the capacitor Csh of the sample & hold circuit 111. As a result, the output voltage of the sample & hold circuit 111 ideally indicates the input voltage Vin. The inverting circuit 112 outputs the inverted output voltage of the sample & hold circuit 111 (ideally the input voltage Vin). Therefore, a charge corresponding to the output voltage of the inversion signal generation circuit 11 is accumulated at the node Ndac (one end of the capacitor Cdac).

Subsequently, in the hold mode, switches SW1d and SWsh switch from on to off, switch SW2 switches from off to on, and switch SW3 switches from on to off. As a result, the sampled input voltage Vin is held in the capacitor Cs, and the voltage inverted from the sampled input voltage Vin is held in the capacitor Cdac.

At this time, the negative feedback circuit 12 performs a sequential comparison operation of the output voltage of the DA converter 123 and the input voltage Vin using the comparator 121 and the sequential comparison register circuit 122.

In the semiconductor device 1a, an error occurs in the capacitor Cs due to the dielectric relaxation phenomenon, and an error of the opposite polarity occurs in the capacitor Cdac due to the dielectric relaxation phenomenon. Therefore, at the voltage Vm of the non-inverting input terminal of the comparator 121, where the other ends of the capacitor Cs and the capacitor Cdac are commonly connected, these error components are cancelled. As a result, the semiconductor device 1 can operate accurately.

In this way, the semiconductor device 1a can achieve an effect equivalent to that of the semiconductor device 1. Furthermore, the semiconductor device 1a is not limited to the above configuration, and can achieve the same effect by applying the common voltage Vcm to the capacitor Cs and the inverted voltage of the common voltage Vcm to the capacitor Cdac in the first sampling mode where the input voltage Vin is not supplied.

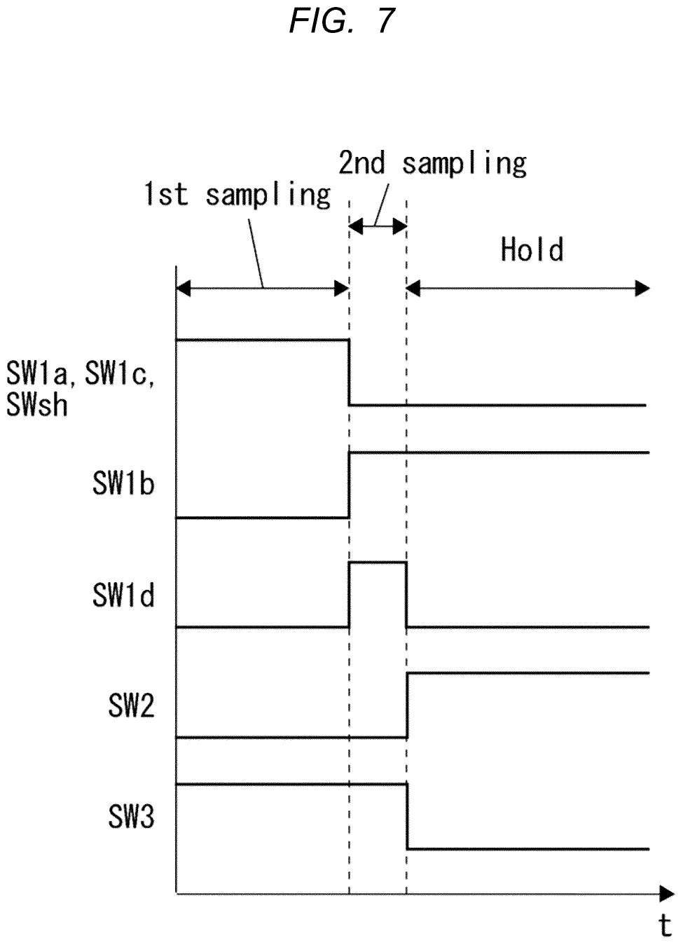

The operation of the semiconductor device 1a is not limited to the example of the timing chart shown in FIG. 6. FIG. 7 is a timing chart showing another example of the operation of the semiconductor device 1a.

First, in the first sampling mode, switches SW1a, SW1c, and SWsh indicate an on state, switch SW1b indicates an off state, switch SW1d indicates an off state, switch SW2 indicates an off state, and switch SW3 indicates an on state. As a result, charges corresponding to the common voltage Vcm and the inverted common voltage (−Vcm) are accumulated at the nodes Ns (one end of the capacitor Cs) and Ndac (one end of the capacitor Cdac), respectively. Furthermore, a charge corresponding to the input voltage Vin is accumulated in the capacitive element Csh of the sample & hold circuit 111.

Subsequently, in the second sampling mode, switches SW1a, SW1c, and SWsh switch from on to off, and switches SW1b and SW1d switch from off to on. As a result, a charge corresponding to the input voltage Vin is accumulated at the node Ns (one end of the capacitive element Cs).

Also, in the second sampling mode, the inverting circuit 112 outputs the inverted output voltage of the sample & hold circuit 111 (ideally the input voltage Vin) held in the capacitive element Csh. Therefore, a charge corresponding to the output voltage of the inverting signal generating circuit 11 is accumulated at the node Ndac (one end of the capacitive element Cdac).

Subsequently, in the hold mode, switch SW1d switches from on to off, switch SW2 switches from off to on, and switch SW3 switches from on to off.

In this way, the semiconductor device la can achieve the same effect as the operation along the timing chart shown in FIG. 6, even with the operation along the timing chart shown in FIG. 7. Furthermore, in the operation along the timing chart shown in FIG. 7, since the output of the inverting signal generating circuit 11 is a fixed voltage held in the second sampling mode, there is a possibility that the inverting signal generating circuit 11 can be simplified. However, it is necessary to accept the disadvantage that if the input voltage Vin changes significantly during the period of the second sampling mode, it cannot follow.

### Second Embodiment

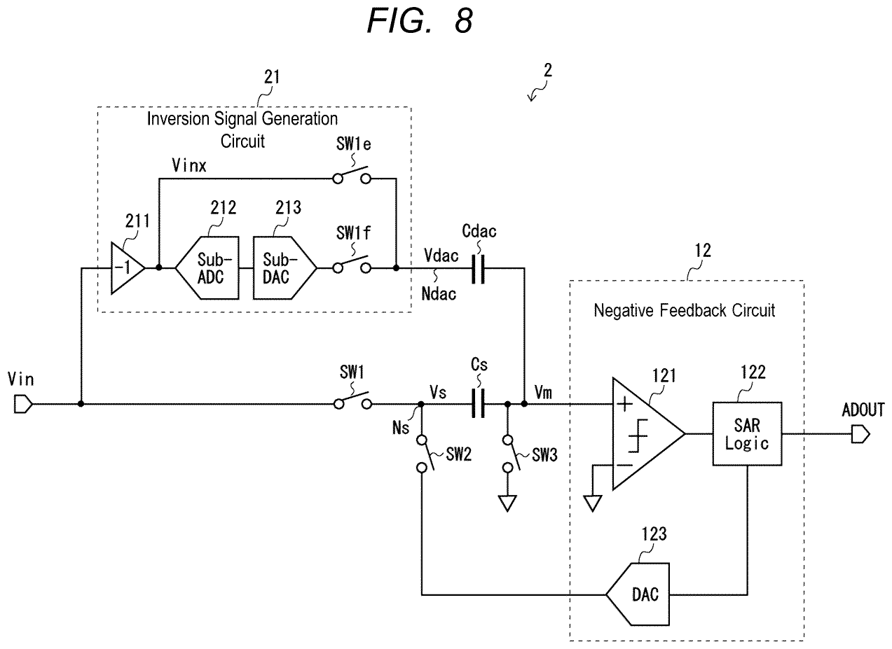

FIG. 8 is a circuit diagram showing a configuration example of a semiconductor device 2 according to the second embodiment. The semiconductor device 2 is equipped with an inverting signal generating circuit 21 instead of the inverting signal generating circuit 11 compared to the semiconductor device 1. The inverting signal generating circuit 21 includes an inverting circuit 211, a sub AD converter 212, a sub DA converter 213, and switches SW1e and SW1f. In the present embodiment, the case where the gain of the inverting circuit 211 is −1 will be described as an example. However, if the capacitive element Cdac is configured to indicate a capacitive value that satisfies Cdac=Cs/k, the gain of the inverting circuit 211 may be −k.

The inverter circuit 211 inverts the input voltage Vin to output the voltage Vinx. The AD converter 212 samples and holds the output voltage Vinx of the inverter circuit 211, and converts the held voltage Vinx into a digital signal for output. The DA converter 213 converts the digital signal output from the AD converter 212 into an analog voltage (equivalent to voltage Vinx) for output. The switch SW1f is provided between the output of the DA converter 213 and the node Ndac. The switch SW1e is provided on a path different from the path where the AD converter 212, DA converter 213, and switch SW1f are provided, among the paths between the output of the inverter circuit 211 and the node Ndac. The switches SW1e and SW1f function as a selection circuit that selects and outputs either the output of the inverter circuit 211 or the output of the DA converter 213.

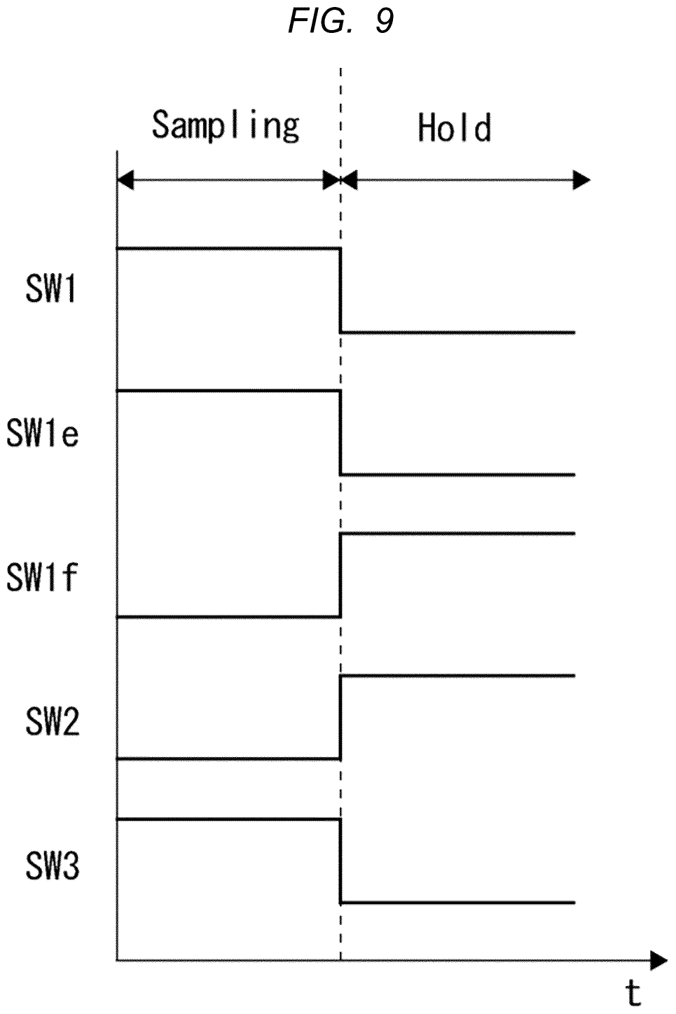

FIG. 9 is a timing chart showing the operation of the semiconductor device 2. Each switch is assumed to turn off by a low-level control signal and turn on by a high-level control signal. The operation modes of the semiconductor device 2 include at least a sampling mode and a hold mode.

First, in the sampling mode, the switch SW1 indicates an on state, the switch SW1e indicates an on state, the switch SW1f indicates an off state, the switch SW2 indicates an off state, and the switch SW3 indicates an on state. As a result, the input voltage Vin is sampled. That is, a charge corresponding to the input voltage Vin is accumulated at the node Ns (one end of the capacitor Cs). As a result, the voltage Vs at the node Ns ideally indicates the input voltage Vin. Also, a charge corresponding to the voltage Vinx, which is the inverted input voltage Vin, is accumulated at the node Ndac (one end of the capacitor Cdac). As a result, the voltage Vdac at the node Ndac ideally indicates the voltage Vinx.

Subsequently, in the hold mode, the switch SW1 switches from on to off, the switch SW1e switches from on to off, the switch SW1f switches from off to on, the switch SW2 switches from off to on, and the switch SW3 switches from on to off. As a result, the sampled input voltage Vin is held in the capacitor Cs, and the voltage Vinx, which is the inverted sampled input voltage Vin, is held in the capacitor Cdac. Also, the AD converter 212 holds the sampled voltage Vinx.

At this time, the negative feedback circuit 12 performs a sequential comparison operation between the output voltage of the DA converter 123 and the input voltage Vin using the comparator 121 and the sequential comparison register circuit 122.

Here, the AD converter 212 converts the held voltage Vinx into a digital signal for output. Then, the DA converter 213 converts the digital signal output from the AD converter 212 into an analog voltage (equivalent to voltage Vinx) and outputs it to the node Ndac. That is, the hold function of the sample & hold circuit 111 is realized by the AD converter 212 and the DA converter 213.

In this way, the semiconductor device 2 according to the present embodiment samples the input voltage Vin and the voltage that inverts it, and holds them in the capacitors Cs and Cdac, respectively, which are commonly connected to the non-inverting input terminal of the comparator 121. As a result, the semiconductor device 2 according to the present embodiment can cancel the error in the input voltage Vin caused by the dielectric relaxation phenomenon in the positive direction and the error in the input voltage Vin caused by the dielectric relaxation phenomenon in the negative direction, and can accurately capture the input voltage Vin and accurately convert it into a digital output signal ADOUT for output.

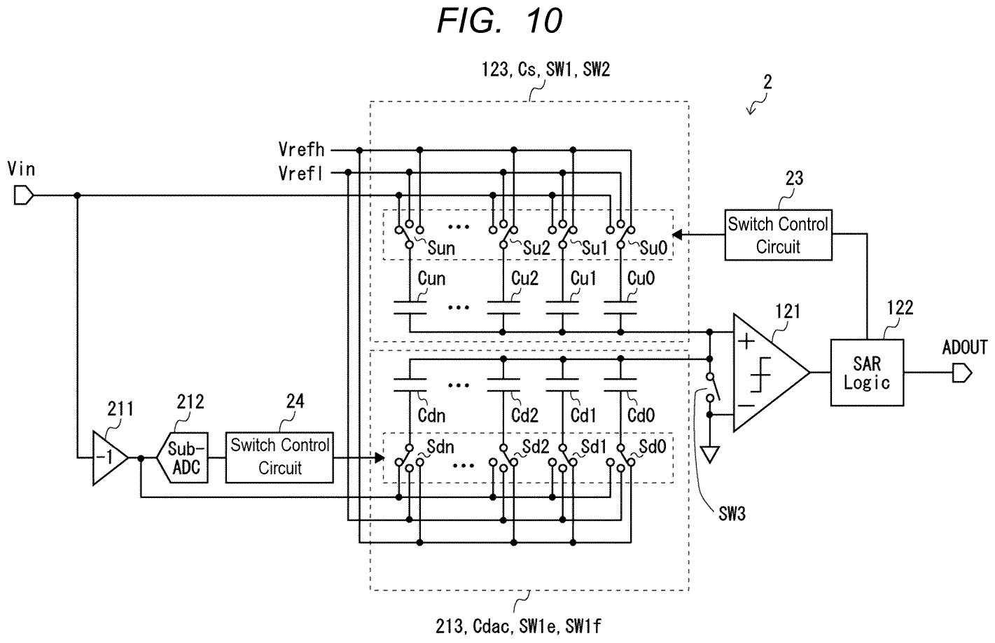

Next, using FIG. 10, a specific configuration example of the semiconductor device 2 will be explained. FIG. 10 is a circuit diagram showing a specific configuration example of the semiconductor device 2.

In the example of FIG. 10, the DA converter 123 includes a capacitance element Cu0, Cu1 indicating the minimum capacitance value 2\hat{ }0·C, n−1 (n is an integer of 2 or more) capacitance elements Cu2 to Cun that are binary-weighted with respect to the capacitance value of the capacitance element Cu1, and switches Su0. Su1 to Sun provided corresponding to each of the capacitance elements Cu0, Cu1 to Cun. Here, the capacitance elements Cu0, Cu1 to Cun are used not only as part of the DA converter 123 but also as a capacitance element Cs. Also, the switches Su0, Su1 to Sun are used not only as part of the DA converter 123 but also as switches SW1, SW2.

The switch control circuit 23 performs charge redistribution for sequential comparison operation as the DA converter 123 and forms the capacitance element Cs by the capacitance elements Cu0, Cu1 to Cun by controlling the on-off of the switches Su0, Su1 to Sun.

Also, in the example of FIG. 10, the DA converter 213 includes a capacitance element Cd0, Cd1 indicating the minimum capacitance value 2\hat{ }0·C, n−1 (n is an integer of 2 or more) capacitance elements Cd2 to Cdn that are binary-weighted with respect to the capacitance value of the capacitance element Cd1, and switches Sd0, Sd1 to Sdn provided corresponding to each of the capacitance elements Cd0, Cd1 to Cdn. Here, the capacitance elements Cd0, Cd1 to Cdn are used not only as part of the DA converter 213 but also as a capacitance element Cdac. Also, the switches Sd0, Sd1 to Sdn are used not only as part of the DA converter 213 but also as switches SW1e, SW1f.

The switch control circuit 24 performs charge redistribution for sequential comparison operation as the DA converter 213 and forms the capacitance element Cdac by the capacitance elements Cd, Cd1 to Cdn by controlling the on-off of the switches Sd0, Sd1 to Sdn.

The other configurations of the semiconductor device 2 shown in FIG. 10 are the same as those of the semiconductor device 2 shown in FIG. 8, so their description is omitted. The semiconductor device 2 shown in FIG. 10 can reduce the circuit scale.

### First Modified Example of Semiconductor Device 2

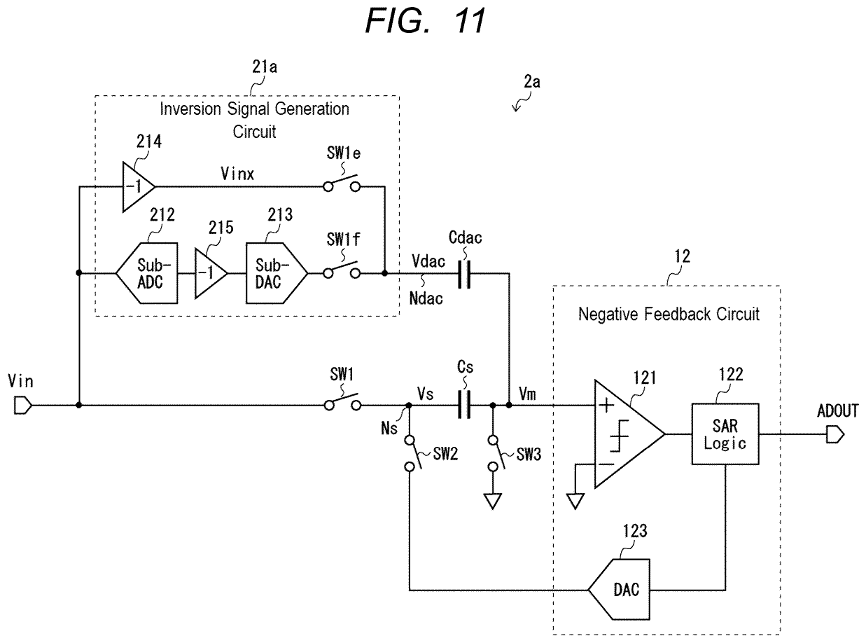

FIG. 11 is a circuit diagram showing the first modified example of the semiconductor device 2 as the semiconductor device 2a. The semiconductor device 2a includes an inversion signal generation circuit 21a instead of the inversion signal generation circuit 21 compared to the semiconductor device 2. The inversion signal generation circuit 21a includes inversion circuits 214, 215 instead of the inversion circuit 211.

The inversion circuit 214 is provided on a path where the switch SW1e is provided between the input terminal Vin and the node Ndac. The inversion circuit 215 is provided on a path where the AD converter 212, the DA converter 213, and the switch SW1f are provided between the input terminal Vin and the node Ndac. Specifically, the inversion circuit 215 is provided between the output of the AD converter 212 and the input of the DA converter 213.

The other configurations of the semiconductor device 2a are the same as those of the semiconductor device 2. so their description is omitted. The semiconductor device 2a can achieve an effect equivalent to that of the semiconductor device 2.

### Second Modified Example of Semiconductor Device 2

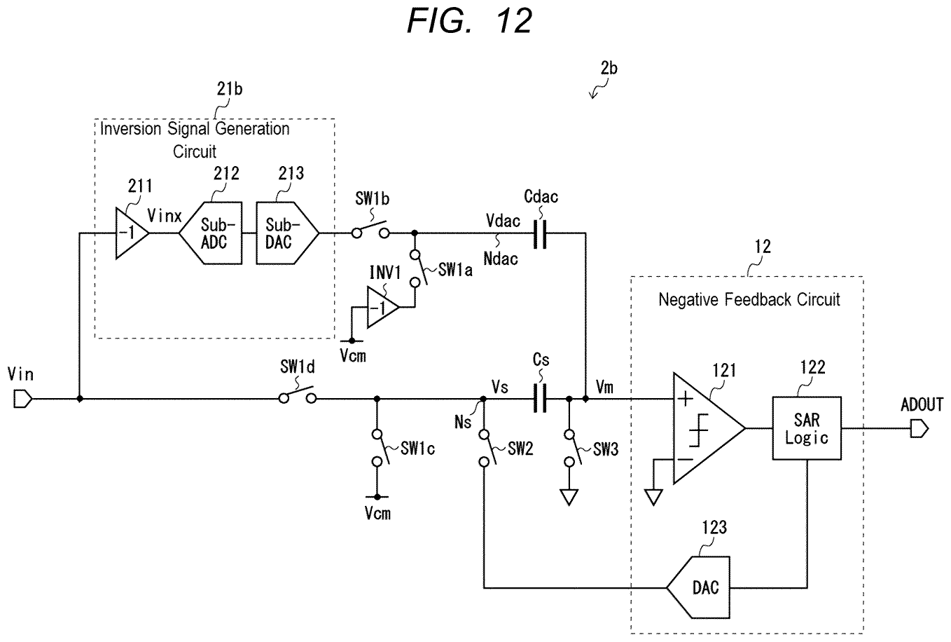

FIG. 12 is a circuit diagram showing the second modified example of the semiconductor device 2 as the semiconductor device 2b. The semiconductor device 2b includes an inversion signal generation circuit 21b instead of the inversion signal generation circuit 21 and switches SW1a, SW1b, SW1c, SW1d instead of the switch SW1 compared to the semiconductor device 2. The switches SW1c, SW1d constitute the first switch circuit, and the switches SW1a, SW1b constitute the second switch circuit. The inversion signal generation circuit 21b includes an inversion circuit 211, a sub AD converter 212, and a sub DA converter 213. In the inversion signal generation circuit 21b, there is one path between the input terminal Vin and the node Ndac.

In the inversion signal generation circuit 21b, the inversion circuit 211 inverts the input voltage Vin to output the voltage Vinx. The AD converter 212 converts the voltage Vinx into a digital signal and outputs it. The DA converter 213 converts the digital signal output from the AD converter 212 into an analog voltage (equivalent to the voltage Vinx) and outputs it.

The switch SW1a is provided between the node Ndac and the inverting circuit INV1 that generates the inverted voltage of the common voltage Vcm. The switch SW1b is provided between the output of the DA converter 213 and the node Ndac. The switch SW1c is provided between the node Ns and the voltage supply terminal Vcm. The switch SW1d is provided between the input terminal Vin and the node Ns. In other words, the switch SW1d is provided where the switch SW1 was provided.

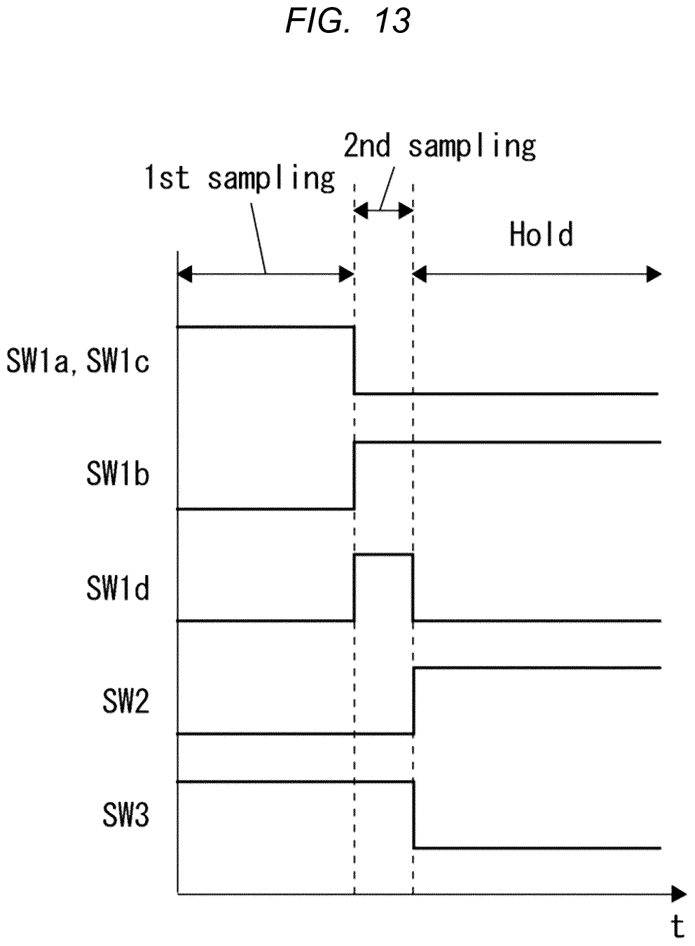

FIG. 13 is a timing chart showing the operation of the semiconductor device 2b. Each switch is assumed to turn off by a low-level control signal and turn on by a high-level control signal. The operation modes of the semiconductor device 2b include at least a sampling mode and a hold mode. The sampling mode is composed of a first sampling mode and a second sampling mode.

First, in the first sampling mode, the switches SW1a and SW1c indicate an on state, the switch SW1b indicates an off state, the switch SW1d indicates an off state, the switch SW2 indicates an off state, and the switch SW3 indicates an on state. As a result, charges corresponding to the common voltage Vcm and the inverted voltage of the common voltage Vcm are accumulated at the node Ns (one end of the capacitor Cs) and the node Ndac (one end of the capacitor Cdac), respectively.

Subsequently, in the second sampling mode, the switches SW1a and SW1e switch from on to off, the switch SW1b switches from off to on, and the switch SW1d switches from off to on. As a result, the input voltage Vin is sampled. In other words, a charge corresponding to the input voltage Vin is accumulated at the node Ns (one end of the capacitor Cs).

Also, in the second sampling mode, the inverting circuit 211 inverts the input voltage Vin and outputs the voltage Vinx. The AD converter 212 converts the voltage Vinx into a digital signal and outputs it. The DA converter 213 converts the digital signal output from the AD converter 212 into an analog voltage (equivalent to the voltage Vinx) and outputs it. Therefore, a charge corresponding to the output voltage of the inversion signal generation circuit 21b is accumulated at the node Ndac (one end of the capacitor Cdac).

Subsequently, in the hold mode, the switch SW1d switches from on to off, the switch SW2 switches from off to on, and the switch SW3 switches from on to off. As a result, the sampled input voltage Vin is held in the capacitor Cs, and the voltage that inverts the sampled input voltage Vin is held in the capacitor Cdac. Also, the AD converter 212 holds the sampled voltage Vinx.

At this time, the negative feedback circuit 12 performs a sequential comparison operation between the output voltage of the DA converter 123 and the input voltage Vin using the comparator 121 and the sequential comparison register circuit 122.

Here, the AD converter 212 converts the held voltage Vinx into a digital signal and outputs it. Then, the DA converter 213 converts the digital signal output from the AD converter 212 into an analog voltage (equivalent to the voltage Vinx) and outputs it to the node Ndac. In other words, the inversion signal generation circuit 21b outputs the inverted voltage of the voltage generated at the node Ns to the node Ndac. As a result, errors generated in the capacitors Cs and Cdac due to dielectric relaxation are canceled.

The semiconductor device 2b can achieve an effect equivalent to that of the semiconductor device 2. Furthermore, the semiconductor device 2b can achieve the same effect by applying the common voltage Vcm to the capacitor Cs and applying the inverted voltage of the common voltage Vcm to the capacitor Cdac in a standby state when the input voltage Vin is not supplied in the first sampling mode, without being limited to the above configuration.

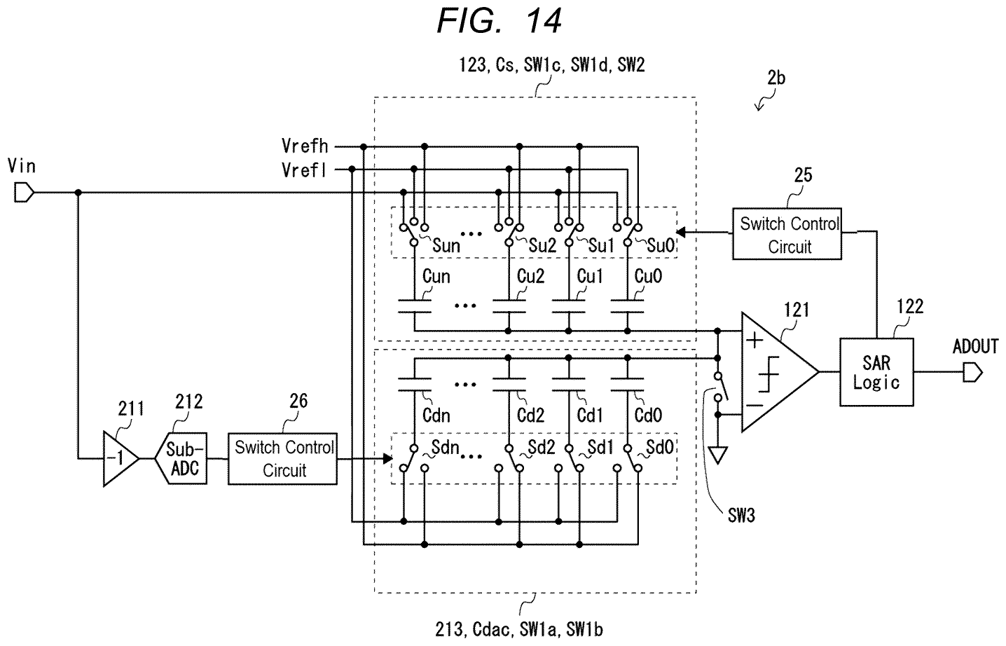

Next, using FIG. 14, a specific configuration example of the semiconductor device 2b will be described. FIG. 14 is a circuit diagram showing a specific configuration example of the semiconductor device 2b.

In the example of FIG. 14, the DA converter 123 includes a capacitance element Cu0, Cu1 indicating the minimum capacitance value 2\hat{ }0·C, n−1 (n is an integer of 2 or more) capacitance elements Cu2 to Cun that are binary-weighted with respect to the capacitance value of the capacitance element Cu1, and switches Su0, Su1 to Sun provided corresponding to each of the capacitance elements Cu0, Cu1 to Cun. Here, the capacitance elements Cu0, Cu1 to Cun are used not only as a part of the DA converter 123 but also as a capacitance element Cs. Also, the switches Su0, Su1 to Sun are used not only as a part of the DA converter 123 but also as switches SW1c, SW1d, SW2.

The switch control circuit 25 performs charge redistribution for the successive comparison operation as the DA converter 123 and forms the capacitance element Cs by the capacitance elements Cu0, Cu1 to Con by controlling the on-off of the switches Su0, Su1 to Son.

Also, in the example of FIG. 14, the DA converter 213 includes a capacitance element Cd0, Cd1 indicating the minimum capacitance value 2\hat{ }0·C, n−1 (n is an integer of 2 or more) capacitance elements Cd2 to Cdn that are binary-weighted with respect to the capacitance value of the capacitance element Cd1, and switches Sd0, Sd1 to Sdn provided corresponding to each of the capacitance elements Cd0, Cd1 to Cdn. Here, the capacitance elements Cd0, Cd1 to Cdn are used not only as a part of the DA converter 213 but also as a capacitance element Cdac. Also, the switches Sd0, Sd1 to Sdn are used not only as a part of the DA converter 213 but also as switches SW1a, SW1b.

The switch control circuit 26 performs charge redistribution for the successive comparison operation as the DA converter 213 and forms the capacitance element Cdac by the capacitance elements Cd0, Cd1 to Cdn by controlling the on-off of the switches Sd0, Sd1 to Sdn.

Other configurations of the semiconductor device 2b shown in FIG. 14 are the same as those of the semiconductor device 2b shown in FIG. 12, so their description is omitted. The semiconductor device 2b shown in FIG. 14 can reduce the circuit scale.

### Third Embodiment

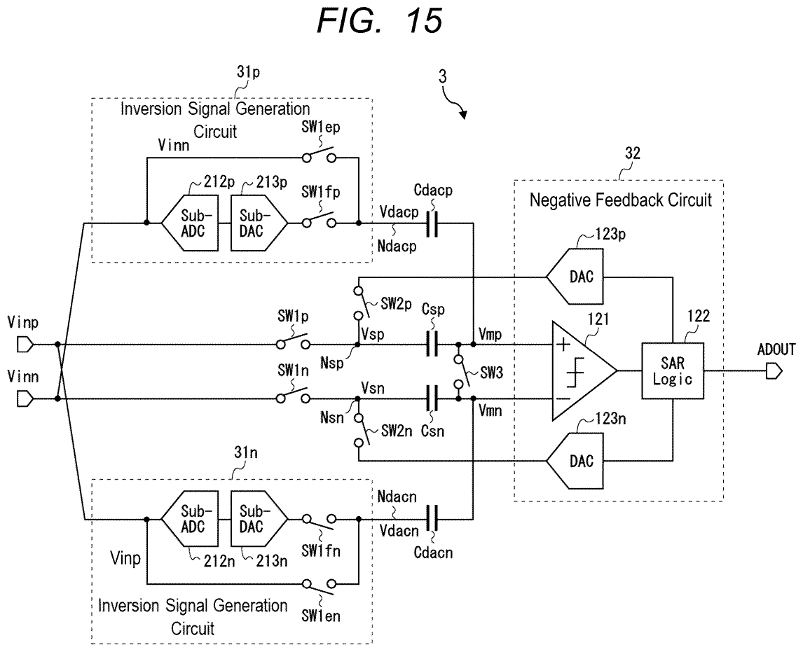

FIG. 15 is a circuit diagram showing a configuration example of the semiconductor device 3 according to the third embodiment. While the semiconductor devices 1, 2 are single-ended successive approximation AD converters, the semiconductor device 3 is a successive approximation AD converter that performs AD conversion for differential input signals.

Specifically, the semiconductor device 3 includes an inversion signal generation circuit 31p, 31n, a negative feedback circuit 32, capacitance elements Csp, Csn, capacitance elements Cdacp, Cdacn, switches SW1p, SW1n, switches SW2p, SW2n, and a switch SW3. The negative feedback circuit 32 includes a comparator 121, a successive comparison register circuit 122, a DA converter 123p, and a DA converter 123n. For example, the switch SW1p constitutes a first switch circuit, and the switch SW1n constitutes a third switch circuit.

First, in the semiconductor device 3, the inversion signal generation circuit 31p, the comparator 121, the successive comparison register circuit 122, the DA converter 123p, the capacitance elements Csp, Cdacp, and the switches SW1p, SW2p, SW3 are mainly used as a circuit for processing a positive side input signal (input voltage) Vinp of a pair of differential input signals. These inversion signal generation circuit 31p, comparator 121, successive comparison register circuit 122, DA converter 123p. capacitance elements Csp, Cdacp, and switches SW1p, SW2p, SW3 correspond to the inversion signal generation circuit 21, comparator 121, successive comparison register circuit 122. DA converter 123, capacitance elements Cs, Cdac, and switches SW1, SW2, SW3 in the semiconductor device 2 shown in FIG. 8, respectively.

Also, in the semiconductor device 3, the inversion signal generation circuit 31n, the comparator 121, the successive comparison register circuit 122, the DA converter 123n, the capacitance elements Csn. Cdacn, and the switches SW1n, SW2n, SW3 are mainly used as a circuit for processing a negative side input signal (input voltage) Vinn of a pair of differential input signals. Moreover, these inversion signal generation circuits 31n, comparator 121, sequential comparison register circuit 122, DA converter 123n, capacitive elements Csn, Cdacn, and switches SW1n, SW2n, SW3 correspond respectively to the inversion signal generation circuit 21, comparator 121, sequential comparison register circuit 122, DA converter 123, capacitive elements Cs, Cdac, and switches SW1, SW2, SW3 in the semiconductor device 2 shown in FIG. 8.

The capacitive element Csp is provided between the non-inverting input terminal of the comparator 121 and the node Nsp. The switch SW1p is provided between the input terminal (hereinafter referred to as input terminal Vinp) where the input voltage Vinp is supplied from outside the semiconductor device 3, and the node Nsp (one end of the capacitive element Csp). The capacitive element Csn is provided between the inverting input terminal of the comparator 121 and the node Nsn. The switch SW1n is provided between the input terminal (hereinafter referred to as input terminal Vinn) where the input voltage Vinn is supplied from outside the semiconductor device 3, and the node Nsn (one end of the capacitive element Csn). The switch SW3 is provided between the non-inverting input terminal and the inverting input terminal of the comparator 121.

The sequential comparison register circuit 122 outputs a digital signal (a control signal that controls each switch of the DA converter 123p, DA converter 123n) according to the comparison result of the comparator 121, and also outputs an output signal ADOUT of a determined digital value. The DA converter 123p converts the digital signal output from the sequential comparison register circuit 122 into an analog voltage and outputs it. The switch SW2p is provided between the output of the DA converter 123p and the node Nsp. The DA converter 123n converts the digital signal output from the sequential comparison register circuit 122 into an analog voltage and outputs it. The switch SW2n is provided between the output of the DA converter 123n and the node Nsn.

The capacitive element Cdacp is provided between the non-inverting input terminal of the comparator 121 and the node Ndacp. The inversion signal generation circuit 31p is provided between the input terminal Vinn and the node Ndacp.

The inversion signal generation circuit 31p includes a sub AD converter 212p, a sub DA converter 213p, a switch SW1ep, and a switch SW1fp. The AD converter 212p, DA converter 213p, switch SW1ep, and switch SW1fp correspond respectively to the AD converter 212, DA converter 213, switch SW1e, and switch SW1f provided in the inversion signal generation circuit 21 shown in FIG. 8. Here, in the inversion signal generation circuit 31p. since the negative side input voltage Vinn (i.e., the voltage obtained by inverting the input voltage Vinp) of the input voltages Vinp, Vinn that constitute a pair of differential signals is input, a circuit corresponding to the inversion circuit 211 is not necessary.

The capacitive element Cdacn is provided between the inverting input terminal of the comparator 121 and the node Ndacn. The inversion signal generation circuit 31n is provided between the input terminal Vinp and the node Ndacn.

The inversion signal generation circuit 31n includes a sub AD converter 212n, a sub DA converter 213n, a switch SW1en, and a switch SW1fn. The AD converter 212n, DA converter 213n, switch SW1en, and switch SW1fn correspond respectively to the AD converter 212. DA converter 213, switch SW1e, and switch SW1f provided in the inversion signal generation circuit 21 shown in FIG. 8. Here, in the inversion signal generation circuit 31n, since the positive side input voltage Vinp (i.e., the voltage obtained by inverting the input voltage Vinn) of the input voltages Vinp, Vinn that constitute a pair of differential signals is input, a circuit corresponding to the inversion circuit 211 is not necessary.

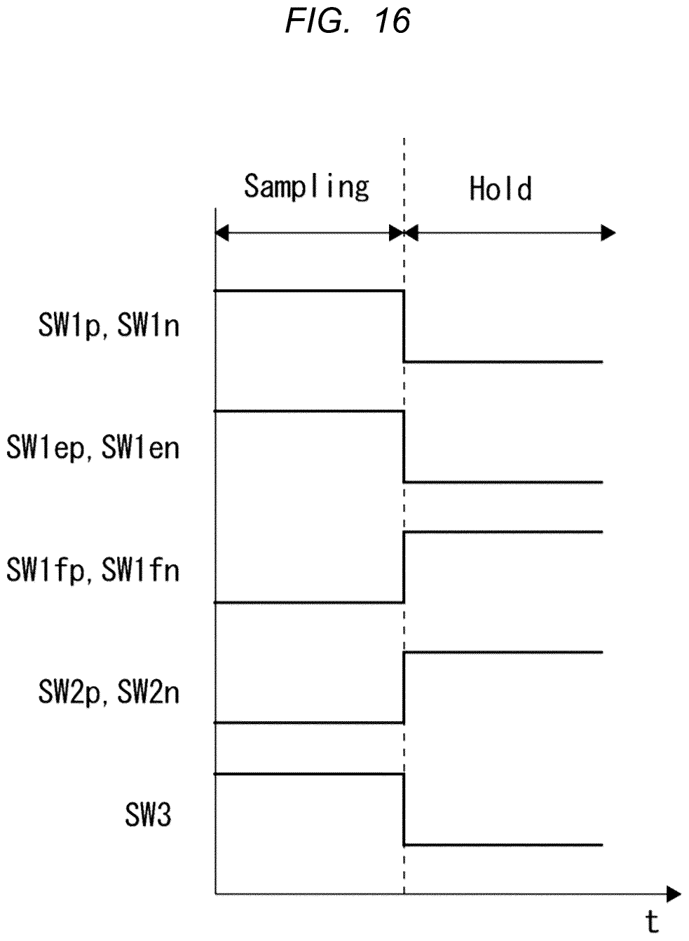

FIG. 16 is a timing chart showing the operation of the semiconductor device 3. Each switch is assumed to turn off by a low-level control signal and turn on by a high-level control signal. Furthermore, the operation modes of the semiconductor device 3 include at least a sampling mode and a hold mode.

Firstly, in the sampling mode, switches SW1p, SW1n indicate an on state, switches SW1ep, SW1en indicate an on state, switches SW1fp, SW1fn indicate an off state, switches SW2p, SW2n indicate an off state, and switch SW3 indicates an on state. As a result, the input voltages Vinp. Vinn are sampled. That is, at node Nsp (one end of the capacitive element Csp), a charge corresponding to the input voltage Vinp is accumulated, and at node Nsn (one end of the capacitive element Csn), a charge corresponding to the input voltage Vinn is accumulated. As a result, the voltage Vsp at node Nsp ideally indicates the input voltage Vinp, and the voltage Vsn at node Nsn ideally indicates the input voltage Vinn. Also, at node Ndacp (one end of the capacitive element Cdacp), a charge corresponding to the voltage Vinn, which is the inverted input voltage Vinp, is accumulated, and at node Ndacn (one end of the capacitive element Cdacn), a charge corresponding to the voltage Vinp, which is the inverted input voltage Vinn, is accumulated. As a result, the voltage Vdacp at node Ndacp ideally indicates the voltage Vinn, and the voltage Vdacn at node Ndacn ideally indicates the voltage Vinp.

Subsequently, in the hold mode, switches SW1p, SW1n switch from on to off, switches SW1ep. SW1en switch from on to off, switches SW1fp, SW1fn switch from off to on, switches SW2p, SW2n switch from off to on, and switch SW3 switches from on to off. As a result, the sampled input voltages Vinp, Vinn are held at the capacitive elements Csp, Csn, respectively, and the sampled input voltages Vinn, Vinp are held at the capacitive elements Cdacp, Cdacn, respectively. Also, the AD converter 212p holds the sampled voltage Vinn. The AD converter 212n holds the sampled voltage Vinp.

At this time, the negative feedback circuit 32 performs a sequential comparison operation between the output voltage of the DA converter 123p and the input voltage Vinp. using the comparator 121 and the sequential comparison register circuit 122.

Also, at this time, the negative feedback circuit 32 performs a sequential comparison operation between the output voltage of the DA converter 123n and the input voltage Vinn, using the comparator 121 and the sequential comparison register circuit 122.

Here, the AD converter 212p converts the held voltage Vinn into a digital signal and outputs it. Then, the DA converter 213p converts the digital signal output from the AD converter 212p into an analog voltage (equivalent to voltage Vinn) and outputs it to node Ndacp. That is, the hold function of the sample & hold circuit 111 is realized by the AD converter 212p and the DA converter 213p.

Also, the AD converter 212n converts the held voltage Vinp into a digital signal and outputs it. Then, the DA converter 213n converts the digital signal output from the AD converter 212n into an analog voltage (equivalent to voltage Vinp) and outputs it to node Ndacn. That is, the hold function of the sample & hold circuit 111 is realized by the AD converter 212n and the DA converter 213n.

In this way, the semiconductor device 3 according to the present embodiment can achieve effects equivalent to those of the semiconductor devices 1, 2. It should be noted that it is difficult to apply the circuit for dielectric relaxation countermeasures applied to the semiconductor device 8 shown in FIG. 26 to the AD converter that performs AD conversion of differential input signals. On the other hand, the semiconductor device 3 according to the present embodiment realizes the application of the circuit for dielectric relaxation countermeasures to the AD converter that performs AD conversion of differential input signals.

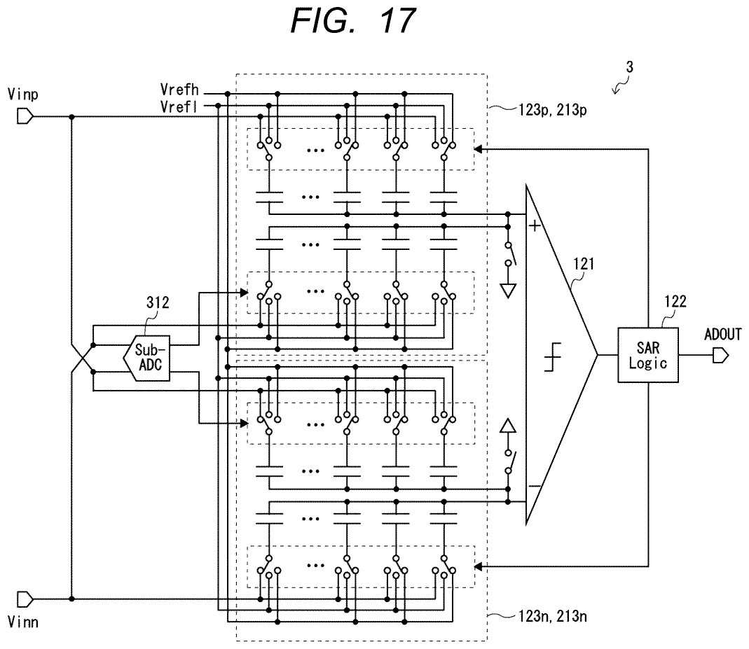

Next, using FIG. 17, a specific configuration example of the semiconductor device 3 will be described. FIG. 17 is a circuit diagram showing a specific configuration example of the semiconductor device 3.

First, in the example of FIG. 17, the DA converters 123p, 213p have the same circuit configuration as the DA converters 123, 213 shown in FIG. 10. The multiple capacitive elements provided in the DA converter 123p are also used as the capacitive element Csp, and the multiple switches provided in the DA converter 123p are also used as the switches SW1p, SW2p. Furthermore, the plurality of capacitive elements provided in the DA converter 213p can also be used as capacitive elements Cdacp, and the plurality of switches provided in the DA converter 213p can also be used as switches SW1ep, SW1fp.

In the example of FIG. 17, the DA converters 123n, 213n have the same circuit configuration as the DA converters 123, 213 shown in FIG. 10. The plurality of capacitive elements provided in the DA converter 123n can also be used as capacitive elements Csn, and the plurality of switches provided in the DA converter 123n can also be used as switches SW1n, SW2n. Furthermore, the plurality of capacitive elements provided in the DA converter 213n can also be used as capacitive elements Cdacn, and the plurality of switches provided in the DA converter 213n can also be used as switches SW1en, SW1fn.

Furthermore, in the example of FIG. 17, the AD converter 312 is used as the AD converters 212p, 212n. In other words, in the example of FIG. 17, the AD converter 312 fulfills the roles of the AD converters 212p, 212n. The other configurations of the semiconductor device 3 shown in FIG. 17 are the same as those of the semiconductor device 3 shown in FIG. 15, so their description is omitted. The semiconductor device 3 shown in FIG. 17 can reduce the circuit scale.

### First Modified Example of Semiconductor Device 3

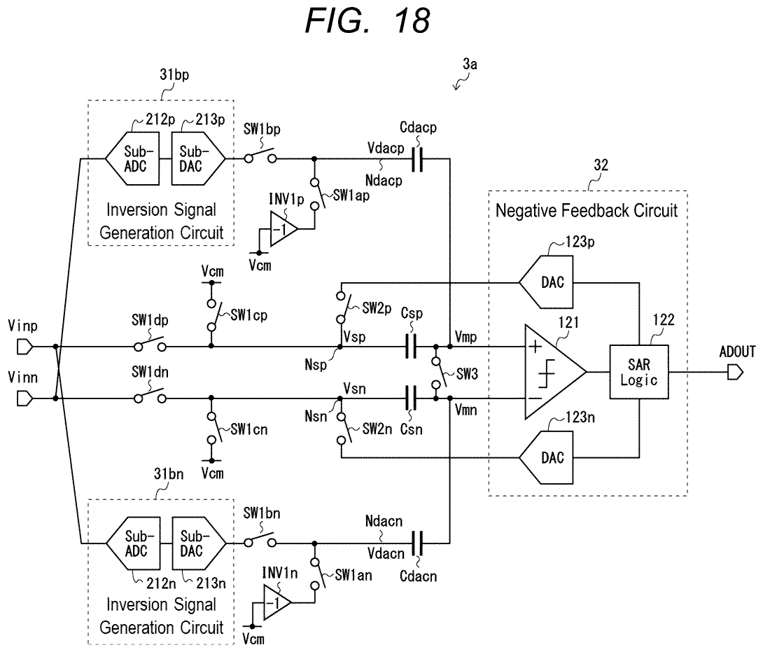

FIG. 18 is a circuit diagram showing the first modified example of the semiconductor device 3 as the semiconductor device 3a. Compared with the semiconductor device 3, the semiconductor device 3a includes the inversion signal generation circuits 31bp, 31bn instead of the inversion signal generation circuits 31p. 31n, and includes the switches SW1ap. SW1bp, SW1cp. SW1dp instead of the switch SW1p, and includes the switches SW1an. SW1bn, SW1cn, SW1dn instead of the switch SW1n. The switches SW1cp. SW1dp constitute the first switch circuit, and the switches SW1ap, SW1bp constitute the second switch circuit. Furthermore, the switches SW1cn, SW1dn constitute the third switch circuit, and the switches SW1an, SW1bn constitute the fourth switch circuit.

The inversion signal generation circuit 31bp includes a sub AD converter 212p and a sub DA converter 213p. The AD converter 212p and the DA converter 213p correspond to the AD converter 212 and the DA converter 213 provided in the inversion signal generation circuit 21b shown in FIG. 12, respectively. Here, in the inversion signal generation circuit 31bp, since the negative side input voltage Vinn (i.e., the voltage obtained by inverting the input voltage Vinp) of the input voltages Vinp, Vinn constituting a pair of differential input signals is input, a circuit corresponding to the inversion circuit 211 is not necessary.

The inversion signal generation circuit 31bn includes a sub AD converter 212n and a sub DA converter 213n. The AD converter 212n and the DA converter 213n correspond to the AD converter 212 and the DA converter 213 provided in the inversion signal generation circuit 21b shown in FIG. 12, respectively. Here, in the inversion signal generation circuit 31bn, since the positive side input voltage Vinp (i.e., the voltage obtained by inverting the input voltage Vinn) of the input voltages Vinp. Vinn constituting a pair of differential input signals is input, a circuit corresponding to the inversion circuit 211 is not necessary.

The switch SW1ap is provided between the node Ndacp and the inverting circuit INV1p that generates the inverted voltage of the common voltage Vcm. The switch SW1bp is provided between the output of the inverted signal generating circuit 31bp and the node Ndacp. The switch SW1cp is provided between the node Nsp and the voltage supply terminal Vcm. The switch SW1dp is provided between the input terminal Vinp and the node Nsp. In other words, the switch SW1dp is provided where the switch SW1p was provided.

The switch SW1an is provided between the node Ndacn and the inverting circuit INV1n that generates the inverted voltage of the common voltage Vcm. The switch SW1bn is provided between the output of the inverted signal generating circuit 31bn and the node Ndacn. The switch SW1cn is provided between the node Nan and the voltage supply terminal Vcm. The switch SW1dn is provided between the input terminal Vinn and the node Nsn. In other words, the switch SW1dn is provided where the switch SW1n was provided.

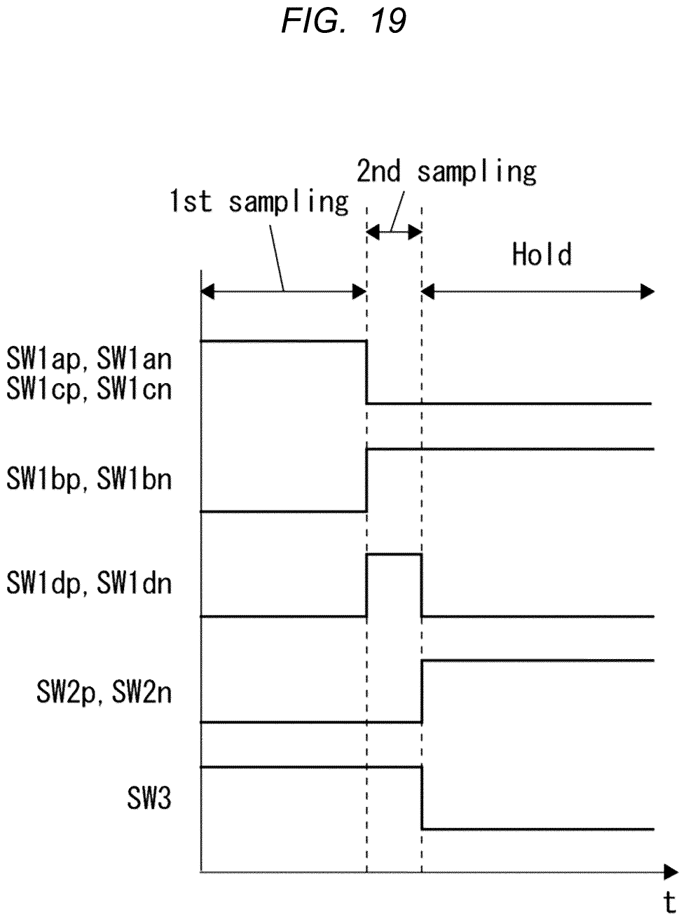

FIG. 19 is a timing chart showing the operation of the semiconductor device 3a. Each switch is turned off by a low-level control signal and turned on by a high-level control signal. The operation modes of the semiconductor device 3a include at least a sampling mode and a hold mode. The sampling mode is composed of a first sampling mode and a second sampling mode.

First, in the first sampling mode, switches SW1ap, SW1an, SW1cp, SW1cn indicate an on state, switches SW1bp, SW1bn indicate an off state, switches SW1dp, SW1dn indicate an off state, switches SW2p. SW2n indicate an off state, and switch SW3 indicates an on state. As a result, charges corresponding to the common voltage Vcm and the inverted voltage of the common voltage Vcm are accumulated at the node Nsp (one end of the capacitor Csp) and the node Ndacp (one end of the capacitor Cdacp), respectively. Also, charges corresponding to the common voltage Vcm and the inverted voltage of the common voltage Vcm are accumulated at the node Nsn (one end of the capacitor Csn) and the node Ndacn (one end of the capacitor Cdacn), respectively.

Subsequently, in the second sampling mode, switches SW1ap, SW1an, SW1cp, SW1cn switch from on to off, switches SW1bp, SW1bn switch from off to on, and switches SW1dp, SW1dn switch from off to on. As a result, the input voltages Vinp and Vinn are sampled. In other words, a charge corresponding to the input voltage Vinp is accumulated at the node Nsp (one end of the capacitor Csp). Also, a charge corresponding to the input voltage Vinn is accumulated at the node Nsn (one end of the capacitor Csn).

Also, in the second sampling mode, the AD converter 212p converts the input voltage Vinn, which is the inverted input voltage Vinp, into a digital signal and outputs it. The DA converter 213p converts the digital signal output from the AD converter 212p into an analog voltage (equivalent to voltage Vinn) and outputs it. Therefore, a charge corresponding to the output voltage of the inverted signal generating circuit 31bp is accumulated at the node Ndacp (one end of the capacitor Cdacp). Also, the AD converter 212n converts the input voltage Vinp. which is the inverted input voltage Vinn, into a digital signal and outputs it. The DA converter 213n converts the digital signal output from the AD converter 212n into an analog voltage (equivalent to voltage Vinp) and outputs it. Therefore, a charge corresponding to the output voltage of the inverted signal generating circuit 31bn is accumulated at the node Ndacn (one end of the capacitor Cdacn).

Subsequently, in the hold mode, switches SW1dp, SW1dn switch from on to off, switches SW2p, SW2n switch from off to on, and switch SW switches from on to off. As a result, the sampled input voltage Vinp is held in the capacitor Csp, and the voltage Vinn, which is the inverted sampled input voltage Vinp, is held in the capacitor Cdacp. Furthermore, the sampled input voltage Vinn is held in the capacitive element Csn, and the voltage Vinp, which is the inversion of the sampled input voltage Vinn, is held in the capacitive element Cdacn. In addition, the AD converter 212p holds the sampled voltage Vinn. The AD converter 212n holds the sampled voltage Vinp.

At this time, the negative feedback circuit 32 performs a sequential comparison operation between the output voltage of the DA converter 123p and the input voltage Vinp. using the comparator 121 and the sequential comparison register circuit 122.

Also, at this time, the negative feedback circuit 32 performs a sequential comparison operation between the output voltage of the DA converter 123n and the input voltage Vinn, using the comparator 121 and the sequential comparison register circuit 122.

Here, the AD converter 212p converts the held voltage Vinn into a digital signal and outputs it. Then, the DA converter 213p converts the digital signal output from the AD converter 212p into an analog voltage (equivalent to voltage Vinn) and outputs it to the node Ndacp. In other words, the inversion signal generation circuit 31bp outputs the inversion voltage of the voltage generated at the node Nsp to the node Ndacp. As a result, errors generated in the capacitive elements Csp, Cdacp due to dielectric relaxation phenomena are cancelled.

In addition, the AD converter 212n converts the held voltage Vinp into a digital signal and outputs it. Then, the DA converter 213n converts the digital signal output from the AD converter 212n into an analog voltage (equivalent to voltage Vinp) and outputs it to the node Ndacn. In other words, the inversion signal generation circuit 31bn outputs the inversion voltage of the voltage generated at the node Nan to the node Ndacn. As a result, errors generated in the capacitive elements Csn, Cdacn due to dielectric relaxation phenomena are cancelled.

The semiconductor device 3a can achieve the same level of effect as the semiconductor device 3. Furthermore, the semiconductor device 3a can achieve the same effect by applying a common voltage Vcm to the capacitive elements Csp, Csn when the input voltages Vinp, Vinn are not supplied in the first sampling mode, and waiting in a state where the inversion voltage of the common voltage Vcm is applied to the capacitive elements Cdacp, Cdacn.

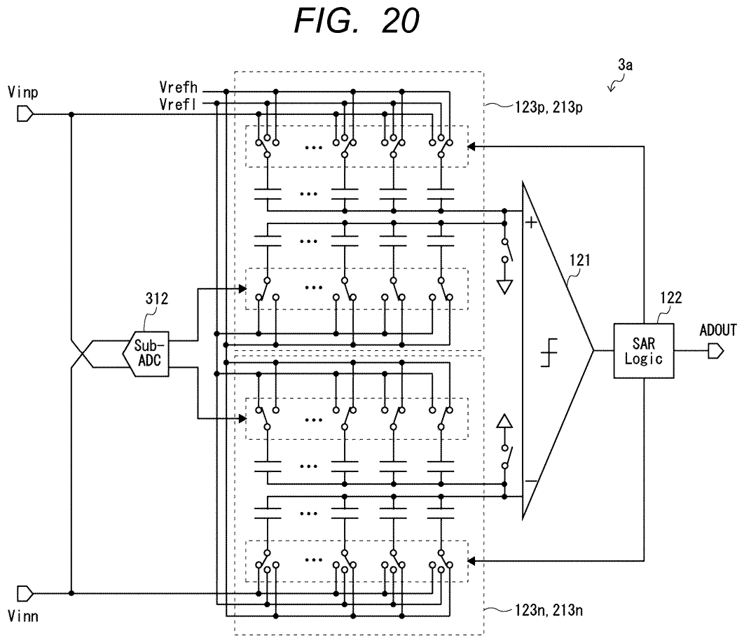

Next, using FIG. 20, a specific configuration example of the semiconductor device 3a will be explained. FIG. 20 is a circuit diagram showing a specific configuration example of the semiconductor device 3a.

First, in the example of FIG. 20, the DA converters 123p, 213p have the same circuit configuration as the DA converters 123, 213 shown in FIG. 14. And, the multiple capacitive elements provided in the DA converter 123p are also used as the capacitive element Csp, and the multiple switches provided in the DA converter 123p are also used as the switches SW1cp, SW1dp, SW2p. In addition, the multiple capacitive elements provided in the DA converter 213p are also used as the capacitive element Cdacp, and the multiple switches provided in the DA converter 213p are also used as the switches SW1ap, SW1bp.

Also, in the example of FIG. 20, the DA converters 123n, 213n have the same circuit configuration as the DA converters 123, 213 shown in FIG. 14. And, the multiple capacitive elements provided in the DA converter 123n are also used as the capacitive element Csn, and the multiple switches provided in the DA converter 123n are also used as the switches SW1cn, SW1dn, SW2n. In addition, the multiple capacitive elements provided in the DA converter 213n are also used as the capacitive element Cdacn, and the multiple switches provided in the DA converter 213n are also used as the switches SW1an, SW1bn.

Furthermore, in the example of FIG. 20, the AD converter 312 is used as the AD converters 212p, 212n. In other words, in the example of FIG. 20, the AD converter 312 performs the roles of both the AD converters 212p and 212n. The other configurations of the semiconductor device 3a shown in FIG. 20 are the same as those of the semiconductor device 3a shown in FIG. 18, so their explanation is omitted. The semiconductor device 3a shown in FIG. 20 can reduce the circuit scale.

### Fourth Embodiment

In the first to third embodiments, it was explained that dielectric relaxation measures are applied to the successive comparison type AD converter, but it is not limited to that. In the present embodiment, we will explain the case where dielectric relaxation measures are applied to a semiconductor device equipped with a negative feedback circuit having an operational amplifier.

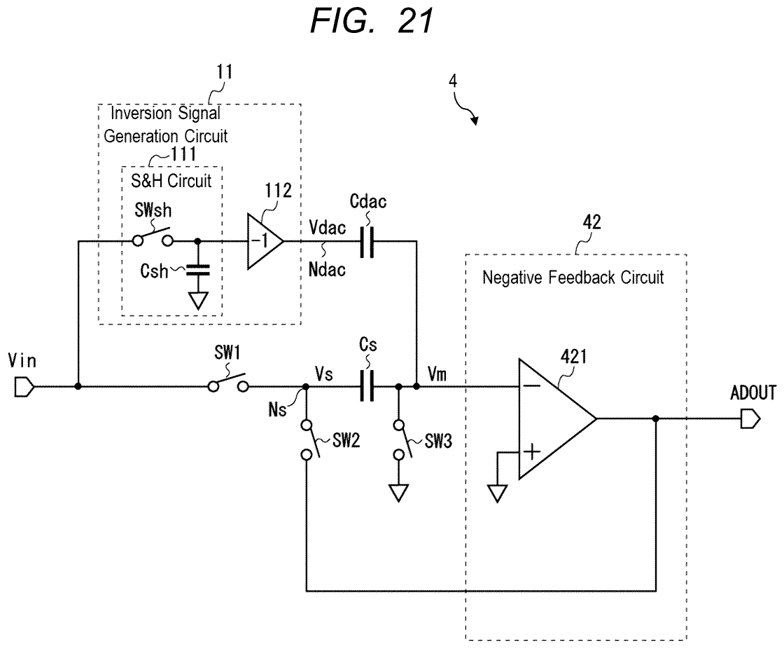

FIG. 21 is a circuit diagram showing a configuration example of a semiconductor device 4 according to the fourth embodiment. The semiconductor device 4 is a sample & hold circuit equipped with a negative feedback circuit having an operational amplifier.

Specifically, the semiconductor device 4 includes an inversion signal generation circuit 11, a negative feedback circuit 42, a capacitive element Cs, a capacitive element Cdac, and switches SW1 to SW3. The inversion signal generation circuit 11 includes a sample & hold circuit 111 and an inversion circuit 112. The negative feedback circuit 42 has an operational amplifier 421.

The capacitive element Cs is provided between the inverting input terminal of the operational amplifier 421 and the node Ns. Switch SW1 is provided between the input terminal Vin and the node Ns (one end of the capacitive element Cs). Switch SW3 is provided between the inverting input terminal (the other end of the capacitive element Cs) of the operational amplifier 421 and the reference voltage terminal Vss. The non-inverting input terminal of the operational amplifier 421 is supplied with the reference voltage Vss.

The operational amplifier 421 amplifies the potential difference between the voltage Vm at the inverting input terminal and the voltage Vss at the non-inverting input terminal and outputs it as an output signal ADOUT. Also, the output voltage of the operational amplifier 421 is fed back and applied to the node Ns via the switch SW2.

The capacitive element Cdac is provided between the inverting input terminal of the operational amplifier 421 and the node Ndac. The inversion signal generation circuit 11 is provided between the input terminal Vin and the node Ndac (one end of the capacitive element Cdac). In the inversion signal generation circuit 11, the sample & hold circuit 111 has a switch SWsh and a capacitive element Csh, and samples and holds the input voltage Vin. The inversion circuit 112 inverts and outputs the output voltage of the sample & hold circuit 111. In the present embodiment, the case where the gain of the inversion circuit 112 is −1 will be explained as an example. However, if the capacitive element Cdac is configured to show a capacitance value that satisfies Cdac=Cs/k, the gain of the inversion circuit 211 may be −k.

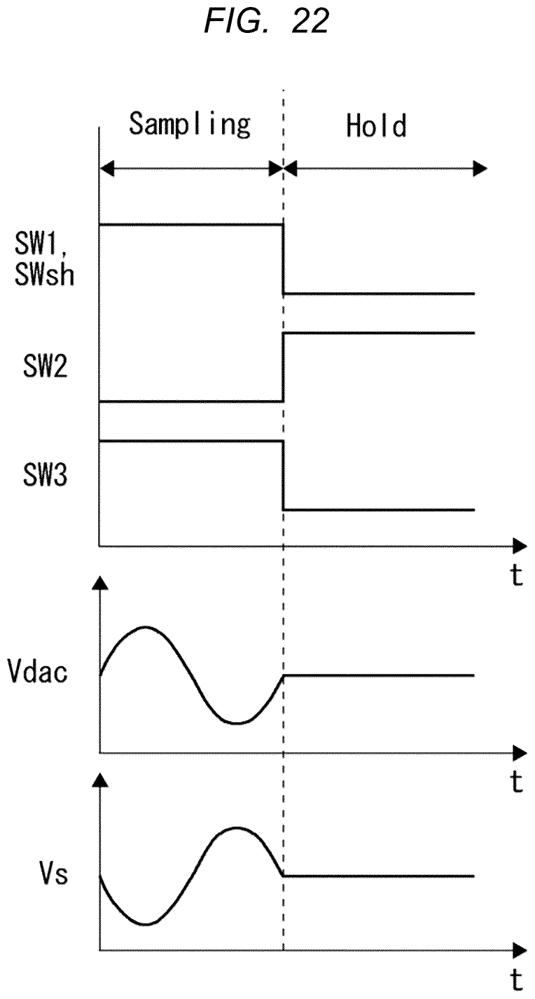

FIG. 22 is a timing chart showing the operation of the semiconductor device 4. Each switch is assumed to turn off by a low-level control signal and turn on by a high-level control signal. Also, the operation modes of the semiconductor device 4 include at least a sampling mode and a hold mode.

First, in the sampling mode, the switches SW1 and SWsh indicate the on state, the switch SW2 indicates the off state, and the switch SW3 indicates the on state. As a result, the input voltage Vin is sampled. That is, a charge corresponding to the input voltage Vin is accumulated at the node Ns (one end of the capacitive element Cs). As a result, the voltage Vs at the node Ns ideally indicates the input voltage Vin. Also, a charge corresponding to the input voltage Vin is accumulated in the capacitive element Csh of the sample & hold circuit 111. As a result, the output voltage of the sample & hold circuit 111 ideally indicates the input voltage Vin. Also, the inversion circuit 112 inverts and outputs the output voltage (ideally the input voltage Vin) of the sample & hold circuit 111. As a result, the voltage Vdac at the node Ndac ideally indicates a voltage that inverts the input voltage Vin.

Then, in the hold mode, the switches SW1 and SWsh switch from on to off, the switch SW2 switches from off to on, and the switch SW3 switches from on to off. As a result, the sampled input voltage Vin is held in the capacitive element Cs, and the voltage that inverts the sampled input voltage Vin is held in the capacitive element Cdac.

In the semiconductor device 4, an error occurs in the capacitive element Cs due to the dielectric relaxation phenomenon, and an error of the opposite polarity occurs in the capacitive element Cdac due to the dielectric relaxation phenomenon. Therefore, at the voltage Vm of the inverting input terminal of the operational amplifier 421, where the other ends of the capacitive element Cs and the capacitive element Cdac are commonly connected, these error components are cancelled. As a result, the semiconductor device 4 can operate accurately.

In this way, the semiconductor device 4 according to the present embodiment samples the input voltage Vin and the voltage that inverts it, and holds them in the capacitive elements Cs and Cdac, respectively, which are commonly connected to the inverting input terminal of the operational amplifier 421. As a result, the semiconductor device 4 according to the present embodiment can cancel the error of the input voltage Vin that occurred in the positive direction due to the dielectric relaxation phenomenon and the error of the input voltage Vin that occurred in the negative direction due to the dielectric relaxation phenomenon, and can accurately capture the input voltage Vin and output the output signal ADOUT accurately.

Although the invention made by the inventor has been specifically described based on the embodiment, the present invention is not limited to the embodiment already described, and it is needless to say that various modifications can be made without departing from the gist thereof.

Furthermore, this disclosure can be realized by executing a computer program on a CPU (Central Processing Unit) to perform some or all of the processing of the semiconductor devices 1 to 4.

The program described above includes a group of instructions (or software code) that, when loaded into a computer, cause the computer to perform one or more functions described in the embodiment. The program may be stored on a non-transitory computer-readable medium or a tangible storage medium. Non-limiting examples of such computer-readable media or tangible storage media include RAM (Random-Access Memory), ROM (Read-Only Memory), flash memory, SSD (Solid-State Drive) or other memory technologies, CD-ROM, DVD (Digital Versatile Disc), Blu-ray (registered trademark) disc or other optical disc storage, magnetic cassette, magnetic tape, magnetic disk storage or other magnetic storage devices. The program may be transmitted on a temporary computer-readable medium or communication medium. Non-limiting examples of such temporary computer-readable media or communication media include electrical, optical, acoustic, or other forms of propagation signals.

What is claimed is:

1. A semiconductor device comprising:
a first capacitor element;
a first switch circuit that applies a first input voltage to one end of the first capacitor element in a sampling mode, and holds the first input voltage in the first capacitor element in a hold mode after the sampling mode;
a first inversion signal generating circuit that generates a voltage that inverts the first input voltage in the sampling mode, and holds the generated voltage in the hold mode;
a second capacitor element to which the voltage generated by the first inversion signal generating circuit is applied at one end; and
a negative feedback circuit that generates an output signal according to the voltage of a first node that is commonly connected to the other end of the first capacitor element and the other end of the second capacitor element in the hold mode, and applies a first feedback signal corresponding to the output signal to one end of the first capacitor element.

2. The semiconductor device according to claim 1, wherein the first inversion signal generating circuit comprises an inversion circuit that generates a voltage that inverts the first input voltage in the sampling mode, and a sample-and-hold circuit that holds the voltage generated by the inversion circuit in the hold mode.

3. The semiconductor device according to claim 1, wherein the first inversion signal generating circuit generates a voltage that inverts the first input voltage with an amplitude according to the capacitance values of the first capacitor element and the second capacitor element.

4. The semiconductor device according to claim 1, wherein the first inversion signal generating circuit comprises:
an inversion circuit that generates a voltage that inverts the first input voltage in the sampling mode;
a first sub-AD converter that holds the voltage generated by the inversion circuit in the hold mode and converts the held voltage into a digital signal;
a first sub-DA converter that converts the digital signal output from the first sub-AD converter into an analog voltage; and
a selection circuit that selects the voltage generated by the inversion circuit in the sampling mode and outputs it as the voltage generated by the first inversion signal generating circuit, and selects the analog voltage output from the first sub-DA converter in the hold mode and outputs it as the voltage generated by the first inversion signal generating circuit.

5. The semiconductor device according to claim 4, wherein the first sub-DA converter comprises a plurality of first sub-capacitor elements and a plurality of first sub-switches provided corresponding to each of the plurality of first sub-capacitor elements, and the plurality of first sub-capacitor elements are also used as the second capacitor element.

6. The semiconductor device according to claim 1, wherein the first inversion signal generating circuit comprises:
a first inversion circuit that generates a voltage that inverts the first input voltage in the sampling mode;
a first sub-AD converter that holds the first input voltage in the hold mode and converts the held first input voltage into a digital signal; a second inversion circuit that inverts and outputs the digital signal output from the first sub-AD converter;
a first sub-DA converter that converts the output signal of the second inversion circuit into an analog voltage; and
a selection circuit that selects the voltage generated by the first inversion circuit in the sampling mode and outputs it as the voltage generated by the first inversion signal generating circuit, and selects the analog voltage output from the first sub-DA converter in the hold mode and outputs it as the voltage generated by the first inversion signal generating circuit.

7. The semiconductor device according to claim 6, wherein the first sub-DA converter comprises a plurality of first sub-capacitance elements and a plurality of first sub-switches provided corresponding to each of the plurality of first sub-capacitance elements, and the plurality of first sub-capacitance elements are also used as the second capacitance element.

8. The semiconductor device according to claim 1,
wherein the sampling mode comprises a first sampling mode and a second sampling mode,
wherein the semiconductor device further comprises a second switch circuit configured to, at the first sampling mode, apply a voltage inverted from the common voltage applied to the first capacitance element to one end of the second capacitance element, and at the second sampling mode and the hold mode, apply the voltage generated by the first inversion signal generation circuit to one end of the second capacitance element, and
wherein the first switch circuit is configured to, at the first sampling mode, apply the common voltage to one end of the first capacitance element, and at the second sampling mode, apply the first input voltage to one end of the first capacitance element.

9. The semiconductor device according to claim 8, wherein the first inversion signal generation circuit comprises:
an inversion circuit that generates a voltage inverted from the first input voltage;
a first sub-AD converter that holds the voltage generated by the inversion circuit in the hold mode and converts the held voltage into a digital signal; and
a first sub-DA converter that converts the digital signal output from the first sub-AD converter into an analog voltage and outputs it as a voltage generated by the first inversion signal generation circuit.

10. The semiconductor device according to claim 1, wherein the negative feedback circuit comprises:
a comparator to which the voltage of the first node is supplied to one input terminal and a reference voltage is supplied to the other input terminal;
a successive comparison register circuit that generates a digital output signal according to the comparison result of the comparator; and
a DA converter that converts the output signal generated by the successive comparison register circuit into an analog voltage and outputs it as the first feedback signal.

11. The semiconductor device according to claim 10,
wherein the DA converter comprises a plurality of capacitance elements and a plurality of switches provided corresponding to each of the plurality of capacitance elements, and
wherein the plurality of capacitance elements provided in the DA converter are also used as the first capacitance element.

12. The semiconductor device according to claim 1, wherein the negative feedback circuit comprises an operational amplifier configured to generate an output signal according to the potential difference between the voltage of the first node and the reference voltage and applies the first feedback signal corresponding to the output signal to one end of the first capacitance element.

13. The semiconductor device according to claim 1, further comprises:
a third capacitor element;
a third switch circuit that applies a second input voltage, which constitutes a differential input signal with a first input voltage, to one end of the third capacitor element in a sampling mode, and holds the second input voltage in the third capacitor element in a hold mode;
a second inversion signal generation circuit that generates a voltage that inverts the second input voltage in the sampling mode and holds the generated voltage in the hold mode: and
a fourth capacitor element to which the voltage generated by the second inversion signal generation circuit is applied at one end,
wherein the negative feedback circuit is configured to generate an output signal according to the potential difference between the voltage of a first node to which the other ends of the first capacitor element and the second capacitor element are commonly connected in the hold mode, and the voltage of a second node to which the other ends of the third capacitor element and the fourth capacitor element are commonly connected, and
wherein the negative feedback circuit is further configured to apply a first feedback signal corresponding to the output signal to one end of the first capacitor element, and a second feedback signal corresponding to the output signal to one end of the third capacitor element.

14. The semiconductor device according to claim 13, wherein the first inversion signal generation circuit comprises:
a first sub-AD converter that holds the second input voltage and converts the held second input voltage into a digital signal in the hold mode;
a first sub-DA converter that converts the digital signal output from the first sub-AD converter into an analog voltage; and
a first selection circuit that selects the second input voltage in the sampling mode and outputs it as a voltage generated by the first inversion signal generation circuit, and selects the analog voltage output from the first sub-DA converter in the hold mode and outputs it as a voltage generated by the first inversion signal generation circuit. wherein the second inversion signal generation circuit comprises:
a second sub-AD converter that holds the first input voltage and converts the held first input voltage into a digital signal in the hold mode;
a second sub-DA converter that converts the digital signal output from the second sub-AD converter into an analog voltage; and
a second selection circuit that selects the first input voltage in the sampling mode and outputs it as a voltage generated by the second inversion signal generation circuit, and selects the analog voltage output from the second sub-DA converter in the hold mode and outputs it as a voltage generated by the second inversion signal generation circuit.

15. The semiconductor device according to claim 14,
wherein the first sub-DA converter comprises a plurality of first sub-capacitor elements and a plurality of first sub-switches provided corresponding to each of the plurality of first sub-capacitor elements,
wherein the plurality of first sub-capacitor elements are also used as the second capacitor element,
wherein the second sub-DA converter comprises a plurality of second sub-capacitor elements and a plurality of second sub-switches provided corresponding to each of the plurality of second sub-capacitor elements, and
wherein the plurality of second sub-capacitor elements are also used as the fourth capacitor element.

16. The semiconductor device according to claim 13,
wherein the sampling mode comprises a first sampling mode and a second sampling mode,
wherein the semiconductor device further comprises:
a second switch circuit configured to, at the first sampling mode, apply a voltage inverted from the common voltage applied to the first capacitance element to one end of the second capacitance element, and at the second sampling mode and the hold mode, apply the voltage generated by the first inversion signal generation circuit to one end of the second capacitance element; and
a fourth switch circuit configured to, at the first sampling mode, apply the voltage inverted from the common voltage to one end of the fourth capacitance element, and at the second sampling mode and the hold mode, apply the voltage generated by the second inversion signal generation circuit to one end of the fourth capacitance element,
wherein the first switch circuit is configured to, at the first sampling mode, apply the common voltage to one end of the first capacitance element, and at the second sampling mode, apply the first input voltage to one end of the first capacitance element, and
wherein the third switch circuit is configured to, at the first sampling mode, apply the common voltage to one end of the third capacitance element, and at the second sampling mode, apply the second input voltage to one end of the third capacitance element.

17. The semiconductor device according to claim 16,
wherein the first inversion signal generation circuit comprises a first sub-AD converter that holds the second input voltage and converts the held second input voltage into a digital signal in the hold mode, and a first sub-DA converter that converts the digital signal output from the first sub-AD converter into an analog voltage and outputs it as a voltage generated by the first inversion signal generation circuit.
wherein the second inversion signal generation circuit comprises a second sub-AD converter that holds the first input voltage and converts the held first input voltage into a digital signal in the bold mode, and a second sub-DA converter that converts the digital signal output from the second sub-AD converter into an analog voltage and outputs it as a voltage generated by the second inversion signal generation circuit.

18. The semiconductor device according to claim 17,
wherein the first sub-DA converter comprises a plurality of first sub-capacitor elements and a plurality of first sub-switches provided corresponding to each of the plurality of first sub-capacitor elements.
wherein the plurality of first sub-capacitor elements are also used as the second capacitor element,
wherein the second sub-DA converter comprises a plurality of second sub-capacitor elements and a plurality of second sub-switches provided corresponding to each of the plurality of second sub-capacitor elements, and
wherein the plurality of second sub-capacitor elements are also used as the fourth capacitor element.

19. The semiconductor device according to claim 13, wherein the negative feedback circuit comprises:
a comparator to which the voltage of the first node is supplied to one input terminal and the voltage of the second node is supplied to the other input terminal;
a successive comparison register circuit that generates a digital output signal according to the comparison result of the comparator;
a first DA converter that converts the output signal generated by the successive comparison register circuit into an analog voltage and outputs it as the first feedback signal; and
a second DA converter that converts the output signal generated by the successive comparison register circuit into an analog voltage and outputs it as the second feedback signal.

20. The semiconductor device according to claim 19,
wherein the first DA converter comprises a plurality of capacitive elements and a plurality of switches provided corresponding to each of the plurality of capacitive elements,
wherein the plurality of capacitive elements provided in the first DA converter are also used as the first capacitive element,
wherein the second DA converter comprises a plurality of capacitive elements and a plurality of switches provided corresponding to each of the plurality of capacitive elements, and
wherein the plurality of capacitive elements provided in the second DA converter are also used as the third capacitive element.
